(19) United States
(12) Patent Application Publication
(10) Pub. No.: US 2026/0299822 A1
(43) Pub. Date: Oct. 1, 2026

(54) WEAK BIT DETECTION IN NON-VOLATILE MEMORY USING ADJUSTED READ CONDITIONS

(71) Applicant: Microchip Technology Incorporated, Chandler, AZ (US)

(72) Inventor: Juha Erik Wikström, Espoo (FI)

(21) Appl. No.: 19/576,268

(22) Filed: Mar. 24, 2026

Related U.S. Application Data
(60) Provisional application No. 63/777,326, filed on Mar. 25, 2025.

(51) Int. Cl. G06F 3/06

(52) U.S. Cl. CPC G06F 3/0655; G06F 3/0604; G06F 3/0679

(57) ABSTRACT

A device includes control circuitry to perform operations with respect to memory accessible to the control circuitry. The memory includes non-volatile memory cells and is organized into memory blocks each including one or more data words. In one or more examples, the control circuitry is to adjust a read condition of a memory block to a skewed read condition for one or more integrity checks on the memory block. The skewed read condition is skewed upward, skewed downward, or both, relative to a nominal read condition. The control circuitry is to determine whether the memory block has at least one weak bit based on results of a comparison of a computed integrity check value from the one or more integrity checks to a stored integrity check value associated with the memory block or to a predetermined value.

### CROSS-REFERENCE TO RELATED APPLICATIONS

This application claims the benefit under 35 U.S.C. § 119(e) of U.S. Provisional Patent Application Ser. No. 63/777,326, filed Mar. 25, 2025, the disclosure of which is hereby incorporated herein in its entirety by this reference.

### TECHNICAL FIELD

Examples relate, generally, to reliability analysis of non-volatile memory, and more particularly to techniques for detecting weak bits in non-volatile memory. Related devices, systems, methods, and processor-readable media are also disclosed.

### BACKGROUND

Most non-volatile memories (NVMs) are based on storing charge on a floating gate. In at least some environments and conditions, NVM bits can lose programming charge slowly over time. Stress-Induced Leakage Current (SILC) is one of the main reliability concerns of NVMs. SILC occurrence increases with the amount of program & erase cycles of the NVM cells. Detecting slow charge loss in non-volatile memory cells over time can be challenging, particularly when the charge loss occurs gradually and does not significantly accelerate with increasing temperature.

### BRIEF DESCRIPTION OF THE DRAWINGS

While this disclosure concludes with claims particularly pointing out and distinctly claiming specific examples, various features and advantages of examples within the scope of this disclosure may be more readily ascertained from the following description when read in conjunction with the accompanying drawings, in which:

FIG. 1 is a block diagram of a computing system including a processing device, according to one or more examples;

FIG. 2 is a block diagram of a computing system including a processing device and a memory device, according to one or more examples;

FIG. 3 is a graph depicting voltage margin development of memory cells and the resulting impact on memory cell reliability and failure;

FIGS. 4A and 4B are diagrams of example relationships between stored levels of a memory cell, decision levels, and read margins for different storage states of the memory cell, where the memory cell is a single-bit cell, according to one or more examples;

FIG. 5 is a diagram of example relationships between stored levels of a memory cell, decision levels, and read margins for different storage states of the memory cell, where the memory cell is a multi-bit cell, according to one or more examples;

FIG. 6 is a diagram illustrating an example memory cell arrangement that may be used to sense a stored level of a non-volatile memory cell, according to one or more examples;

FIG. 7 is a plot of example relationships between a cell current and a sense-gate voltage for different storage levels of a memory cell, according to one or more examples;

FIG. 8A is a diagram of an example non-volatile memory architecture, such as a NOR-type memory device, according to one or more examples;

FIG. 8B is a diagram of example types of non-volatile memory cells in which read conditions may be adjusted by controlling voltages applied to one or more gate terminals or sensing nodes associated with the memory cell;

FIG. 9 is a flowchart of a method for weak bit detection, according to one or more examples;

FIG. 10A is a diagram illustrating an example memory block used for weak bit detection based on integrity checks, according to one or more examples;

FIG. 10B is a diagram illustrating another example memory block used for weak bit detection based on integrity checks, according to one or more examples;

FIG. 11 is a flowchart of a method for weak bit detection, according to one or more examples;

FIG. 12 is a diagram illustrating example memory blocks used for weak bit detection based on read data comparisons, according to one or more examples;

FIG. 13 is a flowchart of an example method for detecting weak bits in non-volatile memory using memory checks or scans performed under different read conditions, according to one or more examples;

FIG. 14A is a diagram illustrating example sensing margins and alert levels of a memory cell which may be used in the scans or checks of the method of FIG. 13;

FIG. 14B is a table illustrating example relationships between results of scans performed under different read conditions and corresponding outcomes when compared with a nominal read result, according to one or more examples;

FIG. 15 is a diagram illustrating example relationships between stored levels of a memory cell and read margins for detecting weak bits and broken bits in non-volatile memory, according to one or more examples;

FIG. 16 is a plot illustrating example sensing conditions used to detect broken bits in a memory cell, according to one or more examples;

FIG. 17 is a diagram illustrating example relationships between stored levels of a memory cell and conditions associated with a safe start for weak bits, according to one or more examples; and

FIG. 18 is a block diagram of circuitry that, in some examples, may be used to implement various functions, operations, acts, processes, and/or methods disclosed herein.

### DETAILED DESCRIPTION

In the following detailed description, reference is made to the accompanying drawings, which form a part hereof, and in which are shown, by way of illustration, specific examples in which the disclosure may be practiced. These examples are described in sufficient detail to enable a person of ordinary skill in the art to practice the disclosure. However, other examples enabled herein may be utilized, and structural, material, and process changes may be made without departing from the scope of the disclosure.

The illustrations presented herein are not meant to be actual views of any particular method, system, device, or structure, but are merely idealized representations that are employed to describe the examples of the disclosure. In some instances, similar structures or components in the various drawings may retain the same or similar numbering for the convenience of the reader; however, the similarity in numbering does not necessarily mean that the structures or components are identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, steps, features, functions, or the like.

It will be readily understood that the components of the examples as generally described herein and illustrated in the drawings could be arranged and designed in a wide variety of different configurations. Thus, the following description of various examples is not intended to limit the scope of the disclosure, but is merely representative of various examples. While the various aspects of the examples may be presented in the drawings, the drawings are not necessarily drawn to scale unless specifically indicated. Throughout the figures, some features are the same as or similar to other features in previously-presented figures, as indicated by the same reference numbers, unless expressly described otherwise.

Furthermore, specific implementations shown and described are only examples and should not be construed as the only way to implement the disclosure unless specified otherwise herein. Elements, circuits, and functions may be shown in block diagram form in order not to obscure the disclosure in unnecessary detail. Conversely, specific implementations shown and described are exemplary only and should not be construed as the only way to implement the disclosure unless specified otherwise herein. Additionally, block definitions and partitioning of logic between various blocks is exemplary of a specific implementation. It will be readily apparent to one of ordinary skill in the art that the disclosure may be practiced by numerous other partitioning solutions. For the most part, details concerning timing considerations and the like have been omitted where such details are not necessary to obtain a complete understanding of the disclosure and are within the abilities of persons of ordinary skill in the relevant art.

Those of ordinary skill in the art will understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the disclosure may be implemented on any number of data signals including a single data signal.

The various illustrative logical blocks, modules, and circuits described in connection with the examples disclosed herein may be implemented or performed with a general purpose processor, a special purpose processor, a digital signal processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer is to execute computing instructions (e.g., software code) related to examples of the disclosure.

The examples may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, other structure, or combinations thereof. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may include one or more elements. As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

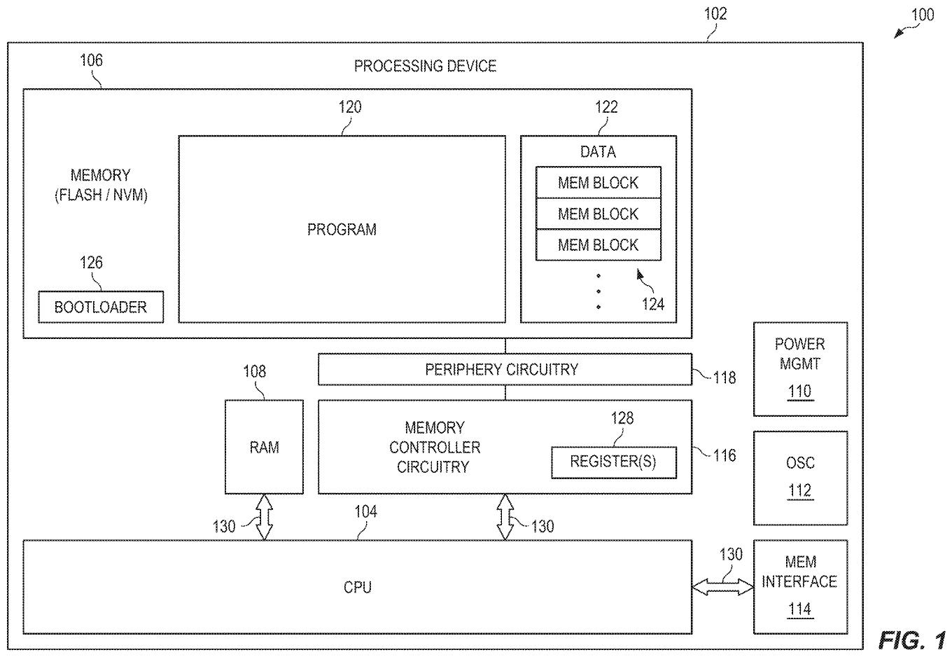

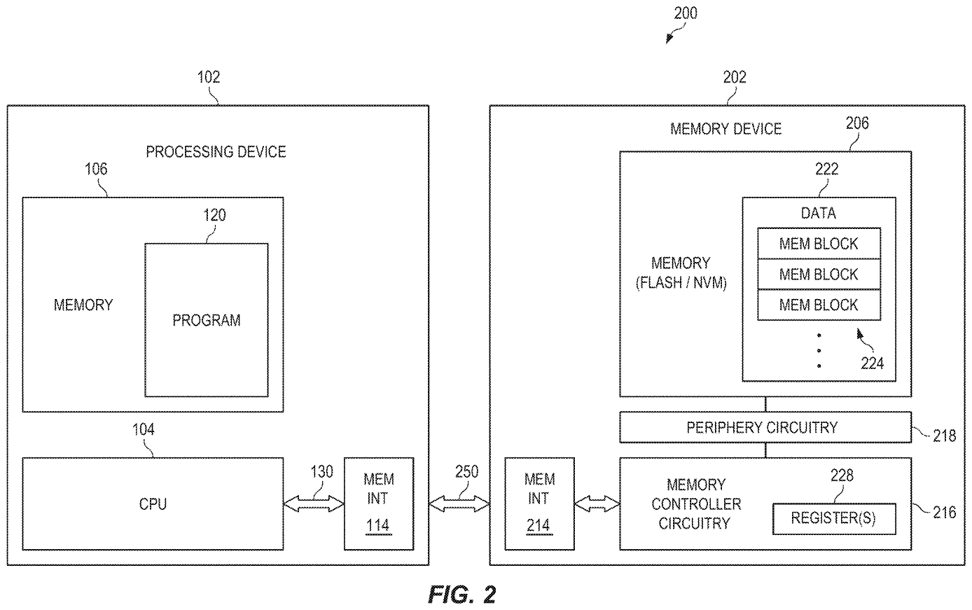

Non-volatile memory (NVM) cells are widely used in processing devices, such as microcontrollers, microprocessors, and stand-alone memory devices, to store program instructions and data that must be retained when power is removed. As these devices operate over time, the NVM cells may experience degradation mechanisms, including gradual charge loss associated with phenomena such as stress-induced leakage current (SILC). Such degradation may occur within the dielectric materials of the memory cell and may gradually reduce the read margin of the affected cells. Because the charge loss may occur slowly and may not strongly accelerate with temperature, the memory cells may continue to function within acceptable read margins for extended periods before eventually degrading into a failure condition. Accordingly, processing devices that utilize NVM may benefit from mechanisms capable of detecting weak or marginal memory cells before functional failures occur. Examples of such devices are illustrated in FIGS. 1 and 2.

FIG. 1 is a block diagram of a computing system 100 including a processing device 102, according to one or more examples. In the illustrated example, computing system 100 includes processing device 102 that corresponds to a microcontroller, microprocessor, system-on-chip (SoC), or other integrated circuit device capable of executing program instructions and interacting with memory resources.

Processing device 102 may include a central processing unit (CPU) 104 configured to execute program instructions and perform processing operations. CPU 104 may communicate with other components of processing device 102 through one or more internal communication paths or buses 130. Processing device 102 may further include random-access memory (RAM) 108 configured to temporarily store data and, at least in some instances, the program instructions used during execution of software programs.

Processing device 102 may further include memory 106 comprising non-volatile memory (e.g., flash memory or other NVM). In one or more examples, memory 106 may include a program region 120 configured to store program instructions and a data region 122 configured to store data. Data region 122 may include one or more memory blocks 124 that may store data words used by processing device 102 during operation. In some examples, memory 106 may also include a bootloader region 126 configured to store instructions executed during device initialization or boot operations.

In one or more examples, processing device 102 may further include memory controller circuitry 116 configured to manage access to memory 106. Memory controller circuitry 116 may include one or more registers 128 that may store configuration information used in controlling memory operations. Memory controller circuitry 116 may communicate with memory 106 through peripheral circuitry 118, which may include circuitry associated with sensing, biasing, or accessing memory cells within memory 106.

Processing device 102 may further include additional circuitry, such as power management circuitry 110 configured to regulate or distribute power within processing device 102, oscillator circuitry 112 configured to provide clock signals used by processing device 102, and memory interface circuitry 114 configured to support communication with external devices or memory components.

FIG. 2 is a block diagram of a computing system 200 including processing device 102 and a memory device 202, according to one or more examples. In computing system 200 of FIG. 2, the processing device corresponds to processing device 102 of FIG. 1 (e.g., a microcontroller, microprocessor, or other processing device as described earlier) and memory device 202 corresponds to a standalone memory device (e.g., external memory), such as a flash memory device or other non-volatile memory device.

Memory device 202 may include memory 206 comprising non-volatile memory cells arranged to store data. In some examples, memory 206 may include a data region 222 including one or more memory blocks 224 configured to store data words. Memory device 202 may also include memory interface circuitry 214 configured to communicate with processing device 102. In one or more examples, processing device 102 and memory device 202 may communicate through an interface connection 250 between memory interface circuitry 114 of processing device 102 and memory interface circuitry 214 of memory device 202. Interface connection 250 may include one or more communication signals, buses, or other interconnection structures used to exchange data and control information between processing device 102 and memory device 202.

Memory device 202 may further include memory controller circuitry 216 configured to control access to memory 206. Memory controller circuitry 216 may include one or more registers 228 configured to store configuration information associated with operation of memory device 202. Memory controller circuitry 216 may communicate with memory 206 through peripheral circuitry 218 that may include circuitry associated with sensing, biasing, or accessing memory cells within memory 206.

As described above with respect to FIGS. 1 and 2, computing systems may include processing devices and memory devices that utilize NVM cells to store data. The operation and reliability of these NVM cells are influenced by physical mechanisms associated with charge storage and retention within the memory cells. More specifically, most NVMs are based on storing charge on a floating gate or similar charge storage structure within a memory cell. Data is represented by the amount of charge stored on the floating gate, which influences the threshold voltage of the associated transistor. In at least some environments and operating conditions, NVM bits can lose stored programming charge slowly over time due to leakage mechanisms within the dielectric materials of the memory cell. Stress-Induced Leakage Current (SILC) is one of the main reliability concerns of NVM devices and is associated with degradation of insulating materials used in the memory cell structure. SILC occurrence generally increases with the number of program and erase cycles experienced by the NVM cells, as repeated electrical stress can gradually damage the oxide layers of the memory cell. As a result, small leakage paths may develop that allow stored charge to escape over time. Detecting slow charge loss that occurs gradually over extended periods, particularly when the charge loss does not strongly accelerate with temperature, is challenging because the memory cells may initially continue to operate within acceptable read margins before eventually degrading into a failure condition.

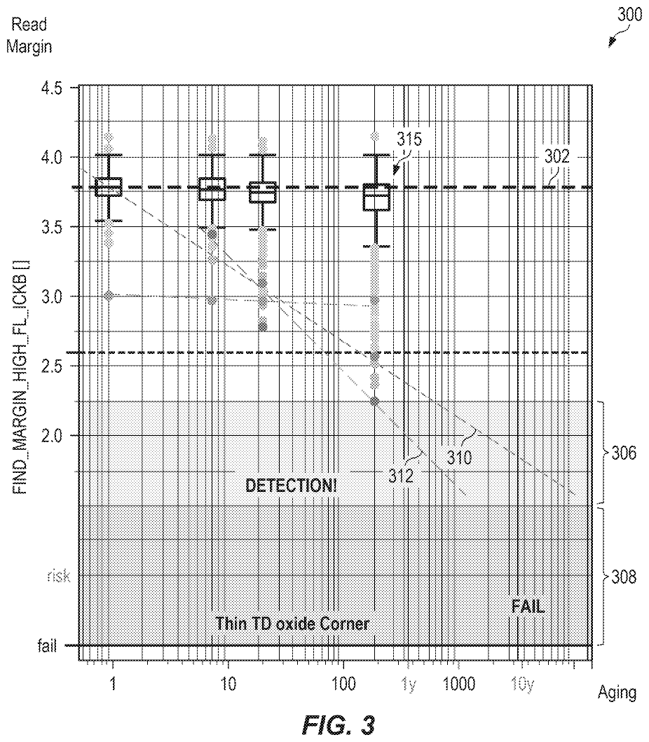

FIG. 3 is a graph 300 depicting observed development of read margin of memory cells over time and the resulting impact on memory cell reliability and failure, according to one or more examples.

In the illustrated example, each data point (e.g., each “dot”) corresponds to a respective memory cell, with the total population including on the order of hundreds of millions of cells (e.g., approximately 983 million cells). The graph reflects observed margin behavior related to degradation and/or intrinsic defects associated with memory cell structures, such as thin dielectric films (e.g., TD oxide layers). Degradation of the materials may lead to leakage mechanisms, including SILC, that reduce the amount of charge retained within a memory cell. Charge loss over time observed in some bits is the result of degradation and/or intrinsic defects that enable slow charge loss. The depicted example shows how physical degradation of the oxides manifests as slow charge loss over time. As the stored charge changes over time or with continued electrical stress, the read margin of the memory cell may decrease.

Graph 300 illustrates read margin values associated with sensing of memory cells as a function of time or stress. In the illustrated example, a reference line 302 corresponds to a nominal read margin level (e.g., approximately 3.7 V, typical cell value), representing memory cells having sufficient margin for reliable sensing under nominal read conditions. Graph 300 further includes statistical distributions 315 representing measured read margin values for populations of memory cells under different stress conditions, aging intervals, or observation points in time. In the illustrated example, these statistical distributions are shown as box-and-whisker plots indicating variation of margin values across large populations of memory cells.

As degradation or defect-related effects progress, portions of the statistical distributions 315 may shift downward from the nominal region near reference line 302 into lower-margin regions. In particular, graph 300 illustrates a first reduced-margin region 306 below the nominal read margin level, in which memory cells may still be readable under nominal read conditions but exhibit reduced read margin. Memory cells within region 306 may correspond to marginal cells or weak bits that are susceptible to failure but have not yet produced erroneous read results. Graph 300 further illustrates a second reduced-margin region 308 below first reduced-margin region 306, in which read results may become unreliable and the probability of bit errors increases. Memory cells second reduced-margin region 308 may therefore correspond to cells approaching or exhibiting functional failure.

Graph 300 also illustrates projected degradation behavior of memory cells over time or stress through trend lines 310 and 312. These dashed slope lines represent interpolated or projected time-to-failure trajectories for particular memory cell populations or operating conditions. As illustrated, the trend lines indicate that read margins may gradually decline over time, transitioning from the nominal margin region near reference line 302 into first reduced-margin region 306 and eventually into second reduced-margin region 308.

In practice, gradual changes in stored charge in individual non-volatile memory cells may lead to single-bit failures after extended periods of operation. Accordingly, FIG. 3 illustrates that progressive reduction in read margin over time may result in memory cells entering first reduced-margin region 306 prior to reaching second-reduced margin region 308 associated with unreliable read behavior. In one or more examples, such reduced-margin conditions may be identified by evaluating memory cells under one or more adjusted read conditions to determine whether the memory cells exhibit reduced read margin relative to one or more decision levels used to define storage states of the memory cells.

In view of the degradation behavior illustrated in FIG. 3, systems such as those illustrated in FIGS. 1 and 2 may include control circuitry configured to detect weak bits associated with non-volatile memory cells.

According to one or more examples of the disclosure, a read condition to sense non-volatile memory cells is modified or adjusted to establish a skewed read condition in one or more scans of the memory cells. By altering the read condition relative to a nominal read condition, such that the read condition is skewed upward or skewed downward, memory cells that have lost charge or have reduced read margin may be detected before a functional failure occurs. Detection of such weak bits may provide early warning of memory degradation and, in some examples, may enable recovery operations such as refreshing or reprogramming the affected memory cells.

In the context of the disclosure, a “scan” of memory for weak bit detection may refer generally to an integrity check performed using a skewed read condition and/or to comparisons of read data obtained from multiple read operations performed under different read conditions, such as a nominal read condition and one or more skewed read conditions. In the disclosure, these approaches may be used individually or in combination to detect weak bits. More generally, a scan may involve reading data from memory using a skewed read condition and evaluating the resulting read data to detect at least one weak bit. In one or more examples, the control circuitry may perform such scans directly, or alternatively may rely on calls to, or built-in behavior of, existing scanning or integrity-check mechanisms. In one or more examples, the techniques described herein may operate in combination with existing integrity-check mechanisms, such as error detection codes (EDCs), error detection and correction codes (EDAC), or similar mechanisms.

In one or more examples, the read condition of the non-volatile memory may be altered to establish a skewed read condition by adjusting sensing parameters associated with a memory read operation. For example, reference currents or reference voltages used by sense amplifiers may be adjusted upward or downward relative to nominal sensing levels to produce a corresponding skewed sensing condition. In some examples, such adjustments may be implemented using circuitry already present in existing memory devices. In other examples, the skewed read condition may be established by adjusting a voltage applied to a sense gate during a read operation. Adjusting the sense-gate voltage may be particularly useful for detecting weak off-cells where conventional techniques, such as lowering the sense amplifier reference current, may not efficiently detect weak bits. Such approaches may be applicable, for example, in memory technologies that do not require a select gate or that include separate select and sense gates. In one or more examples, the skewed read condition may also be applied in a direction that increases the effective sensing margin. For example, upper-limit skewed read conditions may be applied to identify memory cells that exhibit excessively strong conduction characteristics, such as cells that may be shorted or otherwise defective.

In one or more examples, the non-volatile memory may be scanned multiple times using different read conditions, including one or more skewed read conditions. For example, the memory may be read twice, with the read condition skewed upward during one read operation and skewed downward during another read operation relative to the nominal read condition. If a particular bit location produces different read results under the different read conditions, the corresponding memory cell may be identified as a weak bit. Such weak bits may be at risk of changing state over time even if they still pass conventional error detection checks under nominal read conditions. In one or more examples, if one of the skewed read conditions produces data that passes an error detection check, the associated memory cell may be refreshed or repaired by reprogramming the cell. Detection of weak bits may also be performed without relying on error detection codes if the skewed read conditions are selected to probe margins around the intrinsic state of the memory cell.

Traditional error detection mechanisms such as CRC operations alone cannot locate a weak memory cell and generally only detect already corrupted memory data. Error correction code (ECC) mechanisms may provide some early detection capability and may correct certain single-bit errors. However, ECC mechanisms typically require additional memory cells and therefore increase die area. Furthermore, ECC mechanisms generally detect hard errors and may not detect conditions such as weak initial programming or gradual charge loss before a bit failure occurs. In one or more examples, the techniques described herein may be used in combination with CRC, ECC, or other integrity-check mechanisms to provide an additional level of detection capability, particularly when such mechanisms operate on data read using one or more skewed read conditions.

Advantages of the techniques described herein may include one or more of the following. In one or more examples, the techniques provide improved functional safety for non-volatile memory. In one or more examples, the techniques provide early warning of charge loss or memory degradation through evaluation of memory data under skewed read conditions. In one or more examples, weak initial programming conditions may be detected. In one or more examples, the techniques may be implemented with minimal silicon overhead and with essentially no practical limitation on the number of weak bits that can be detected. The techniques may also complement existing error detection or correction mechanisms. In one or more examples, such techniques may improve functional safety for NVM used in safety-critical environments, such as automotive systems.

With respect to FIGS. 1 and 2, CPU 104 may execute processor-executable instructions to perform operations described herein involving detection of weak bits in memory. CPU 104 executing the processor-executable instructions may therefore represent one example of “control circuitry” used to perform such operations. In one or more alternative examples, the control circuitry may include hardware control logic configured to perform the operations described herein. As one or more examples, the hardware control logic may be hardware state machine circuitry, built-in self-test (BIST) circuitry, memory management unit (MMU) circuitry, or other hardware logic. In one or more examples, the operations of the disclosure may be performed with respect to memory 106 of processing device 102 as illustrated in FIG. 1, while in one or more other examples, the operations may be performed with respect to memory 206 of memory device 202 as illustrated in FIG. 2.

In one or more specific examples, weak bit scanning according to the disclosure may be implemented using start-up firmware stored in ROM, such as boot ROM of a microcontroller or microprocessor. In one or more examples, the ROM for weak bit scanning is hard-wired mask ROM that is not susceptible to SILC or similar aging effects. In other examples, automated weak bit scanning may be implemented using BIST circuitry associated with the processing device. In even other examples, weak bit scanning may be implemented using start-up firmware in combination with BIST circuitry associated with the processing device. In one or more examples, the techniques may be implemented with relatively small silicon overhead. In one or more examples, the techniques may be implemented using internal circuitry without reliance on external production testers. In one or more other examples, degradation of memory charge may be evaluated using external production testers capable of measuring charge retention characteristics of the memory cells.

According to one or more examples of the disclosure, the control circuitry (e.g., CPU 104) is configured to perform operations with respect to memory (e.g., memory 106 or memory 206) accessible to the control circuitry. The memory may comprise non-volatile memory cells organized into one or more memory blocks (e.g., memory blocks 124 of memory 106 or memory blocks 224 of memory 206), where each memory block comprises one or more data words. In one or more examples, the control circuitry may adjust a read condition of a memory block to a skewed read condition relative to a nominal read condition. This adjustment may be made for one or more integrity checks on the memory block for the detection of weak bits. In one or more examples, a weak bit may correspond to a stored level of a non-volatile memory cell within memory (e.g., memory 106 or memory 206) having a read margin that is less than a minimum acceptable read margin relative to one or more decision levels that define a storage state of the cell.

In one or more examples, the integrity checks may be used to compute an integrity check value that can be compared with a stored integrity check value associated with the memory block or to a predetermined value. Based at least partially on results of the comparison, the control circuitry may determine whether the memory block has at least one weak bit. For example, the control circuitry may determine the memory block to have the at least one weak bit at least partially based on the results indicating a mismatch between the computed integrity check value and the stored integrity check value, or alternatively determine the memory block to be free of weak bits at least partially based on the results indicating a match between the computed integrity check value and the stored integrity check value.

In one or more other examples, the integrity checks may comprise a syndrome-based error detection operation, in which a syndrome is computed based on data of the memory block, including any stored integrity check value associated with the memory block. The computed syndrome may represent an integrity check value that is evaluated relative to a predetermined value, such as zero (0), where a zero-valued syndrome indicates that the data satisfies the integrity check condition and a non-zero syndrome indicates that an error is present. For example, the control circuitry may determine the memory block to have the at least one weak bit at least partially based on results indicating that the computed syndrome does not match the predetermined value (e.g., is non-zero), or may determine the memory block to be free of weak bits at least partially based on results indicating that the computed syndrome matches the predetermined value (e.g., is equal to zero).

In one or more examples, the integrity checks may include CRC operations or EDAC operations performed on data read from the memory block. In one or more examples, such CRC or EDAC operations may be performed by circuitry associated with the control circuitry (e.g., CPU 104), by circuitry of memory controller circuitry (e.g., memory controller circuitry 116 or memory controller circuitry 216), or by other circuitry coupled to bus 130.

The skewed read condition may be established by adjusting sensing parameters associated with reading the non-volatile memory cells. For example, the control circuitry may adjust a reference voltage or current used by sense amplifiers of the peripheral circuitry (e.g., peripheral circuitry 118 or peripheral circuitry 218) relative to a nominal read reference, or may adjust bias conditions associated with transistors of the non-volatile memory cells, such as a source-to-gate voltage relative to a nominal read source-to-gate voltage. In one or more other examples, the control circuitry may establish the skewed read condition by setting values of one or more configuration registers (e.g., registers 128 or registers 228) that influence sensing parameters, or by adjusting signals applied to one or more inputs of the memory (e.g., memory 106 or memory 206) that affect read conditions of the non-volatile memory cells.

According to one or more other examples of the disclosure, the control circuitry may be configured to perform multiple read operations on a memory block under different read conditions and compare resulting read data to determine whether the memory block contains at least one weak bit. In one or more examples, the control circuitry may perform two or more read operations on a memory block (e.g., from memory blocks 124 of memory 106 or memory blocks 224 of memory 206), such as a first read operation and a second read operation. For at least one of the read operations, the control circuitry may adjust a read condition of the memory block to a skewed read condition relative to a nominal read condition. The skewed read condition may be skewed upward, skewed downward, or both, relative to the nominal read condition. In one or more examples, the control circuitry may determine whether the memory block has at least one weak bit at least partially based on comparison between first read data obtained during the first read operation and second read data obtained during the second read operation. In one or more examples, read data obtained during the read operations may be temporarily stored in RAM (e.g., RAM 108) so that the control circuitry can compare the read results. In one or more examples, the control circuitry may determine that the memory block has the at least one weak bit at least partially based on identifying a mismatch between the first read data and the second read data, and may determine that the memory block is free of weak bits at least partially based on identifying a match between the first read data and the second read data. In one or more examples, the control circuitry may further identify at least one weak bit location of the memory block based on bit differences between corresponding bits of the first read data and the second read data.

In one or more examples, comparison of read results obtained under different read conditions may therefore enable identification of weak bits associated with memory cells having reduced read margins within the memory blocks. In one or more examples, the first read operation is performed using the nominal read condition and the second read operation is performed using the skewed read condition (e.g., skewed upwards or downwards), or vice versa. In one or more other examples, the first read operation is performed using a first skewed read condition (e.g., skewed upwards) and the second read operation is performed using a second skewed read condition (e.g., skewed downwards).

In one or more examples, a weak bit may correspond to a stored level of a non-volatile memory cell within memory (e.g., memory 106 or memory 206) having a read margin outside a threshold margin range relative to one or more decision levels that define a storage state of the cell. The skewed read condition may be established for the multiple read operations by modifying sensing parameters used during read operations of the non-volatile memory cells. As discussed above, such modifications may include adjusting sensing references, bias conditions of memory cell transistors, configuration register values, or signals applied to inputs of the memory.

In one or more examples, the control circuitry may provide an indication that at least one weak bit has been detected. The indication may be provided at an output or interface associated with the processing device or memory device so that a user, system controller, or diagnostic process may identify the presence of the weak bit condition. For example, the indication may be provided through a status register, interrupt signal, debug interface, system bus interface, memory interface, communication interface, or other output mechanism of the processing device or memory device. In some implementations, the indication may be accessible through firmware or software executing on the processing device, through diagnostic or test interfaces (e.g., Joint Test Action Group (JTAG) or other debug ports), or through external communication interfaces used to report system status.

With reference back to computing system 100 of FIG. 1, a microcontroller or microprocessor may include embedded memory containing non-volatile memory cells integrated on the same semiconductor die as the processor core. The processor may interact with the embedded memory through an internal memory interface or bus structure (e.g., bus 130) that connects the processor core, memory controller circuitry 116, and the memory arrays of memory 106. Through this interface, the control circuitry (e.g., CPU 104 or other control logic) may access memory blocks 124 to perform operations for weak bit detection, such as memory read operations, integrity checks, and other operations described herein.

In many microcontrollers, embedded memory such as flash or Electrically Erasable Programmable ROM (EEPROM) is connected to the processor core through an internal system bus, such as instruction and data paths included in bus 130. Memory controller circuitry 116 may be positioned between CPU 104 and memory 106 to manage sensing, programming, and other operations associated with the non-volatile memory cells. The control circuitry may also perform operations for weak bit detection through this interface. In one or more examples, the control circuitry may perform operations to adjust read conditions on memory blocks 124 and to perform, initiate, or allow integrity checks on the memory blocks. In one or more other examples, the control circuitry may perform multiple read operations on memory blocks 124 under different read conditions and compare resulting read data to determine whether a weak bit is present. In one or more examples, the processor may write to configuration registers 128 within memory controller circuitry 116 through this interface to influence operating modes or sensing parameters associated with memory reads.

With reference back to computing system 200 of FIG. 2, when a processor interacts with an external stand-alone memory device containing non-volatile memory cells, such as memory device 202, the processor communicates with the memory through external interface circuitry and off-chip signal lines. For example, memory interface circuitry 114 of processing device 102 may communicate with memory interface circuitry 214 of memory device 202 through interface connection 250. Through this interface, the control circuitry may access memory blocks 224 of memory 206 and perform operations for weak bit detection, such as read operations, integrity checks, or adjustment of read conditions used to sense the non-volatile memory cells.

Memory device 202 may include memory controller circuitry 216 that manages access to memory 206 and associated peripheral circuitry 218. In one or more examples, configuration registers 228 within memory controller circuitry 216 may be written by processing device 102 through interface connection 250 to influence operating modes or sensing parameters associated with memory reads. Through such interactions, the control circuitry may perform operations for weak bit detection, including adjusting read conditions, performing integrity verification operations, and detecting weak bits within memory blocks.

In one or more examples, the control circuitry used for weak bit detection is separate and apart from the memory, the memory controller circuitry, and/or the peripheral circuitry. In one or more examples, the control circuitry may determine and control the extent of the one or more adjustments made for detecting weak bits.

Computing systems such as those illustrated in FIGS. 1 and 2 may include circuitry capable of performing integrity verification operations on data stored in memory blocks (e.g., memory blocks 124 or memory blocks 224). In one or more examples, integrity verification operations may include CRC operations, EDAC operations, or similar integrity checking mechanisms applied to data read from memory cells. Integrity verification circuitry may be implemented in various locations within the computing system. In some examples, CRC or EDAC operations may be performed by circuitry associated with CPU 104, by logic within memory controller circuitry 116 or memory controller circuitry 216, or by dedicated hardware engines coupled to bus 130. In other examples, firmware executed by CPU 104 may compute CRC values or initiate integrity verification operations for data stored in selected memory blocks.

During an integrity check, data read from a memory block may be processed to compute an integrity check value that can be compared with a stored integrity value associated with the memory block. In some examples, the integrity check may be performed while the memory is read under a skewed read condition relative to a nominal read condition. Based on the comparison of the computed integrity check value and the stored integrity check value, the control circuitry may determine whether the memory block contains at least one weak bit.

In one or more examples, registers associated with the memory controller circuitry may be used to influence sensing parameters associated with memory read operations. For example, registers 128 of memory controller circuitry 116 or registers 228 of memory controller circuitry 216 may store configuration values that control circuitry responsible for establishing sensing conditions during reads of non-volatile memory cells. Values written to these registers may influence circuitry that generates sensing reference levels, bias conditions, or other parameters used by sense amplifiers to detect the stored level of memory cells. For example, a register value may control selection of a reference voltage level or provide a control value to circuitry that generates a reference voltage or current used during sensing. In one or more other examples, register values may influence bias currents, threshold selection circuitry, or other circuits associated with sensing operations within peripheral circuitry 118 or peripheral circuitry 218. Through this mechanism, the control circuitry may adjust sensing parameters relative to nominal read conditions. Such adjustments may be used to establish skewed read conditions when performing integrity checks or when performing multiple read operations on a memory block to evaluate the reliability of stored data.

Thus, in one or more examples, sensing conditions used when reading memory cells may be intentionally modified relative to a nominal read condition. Such adjustments may allow the control circuitry to evaluate the stability of stored data or identify memory cells having reduced read margins. In one or more examples, the control circuitry may adjust read conditions by writing values to registers associated with the memory controller or memory device that influence sensing parameters used during read operations. Changing the stored value of such registers may shift sensing reference levels or bias conditions used by sense amplifiers, thereby establishing a skewed read condition relative to the nominal read condition.

In one or more alternative examples, read conditions may be influenced through signals applied to one or more inputs associated with the memory device. Such signals may include analog or digital control signals that influence sensing circuitry, including signals affecting reference voltage levels, bias currents, or other parameters used when detecting the state of memory cells. These signals may be generated by control circuitry such as digital control logic, digital-to-analog converters, or other circuits capable of producing adjustable voltage or current levels.

In one or more further examples, the read condition may be influenced by modifying bias voltages applied to transistors associated with the memory cells, such as adjusting a source-to-gate voltage applied to memory cell transistors or associated access transistors. By adjusting such bias conditions relative to nominal read conditions, the operating point under which the memory cells are sensed may be shifted. Reads performed under such adjusted sensing conditions may then be compared with reads performed under nominal conditions to detect weak bits or identify locations of weak bits within a memory block.

In one or more examples, and as part of the mechanisms described above for adjusting read conditions, one or more registers may be dedicated or specifically configured for adjusting or skewing read conditions, such as for use in weak-bit detection or related diagnostic operations. For example, the registers may include one or more read condition registers to define a nominal or selected read condition, and one or more read condition offset registers to adjust or skew the read condition relative to the nominal read condition. In one or more implementations, the registers may control electrical sensing parameters, such as reference current registers, reference voltage registers, bias control registers, or sense-gate voltage registers, which influence operation of sense amplifiers or associated memory cell transistors during read operations. By writing values to these registers, the control circuitry may establish nominal and skewed read conditions used to evaluate read margins and/or detect weak bits.

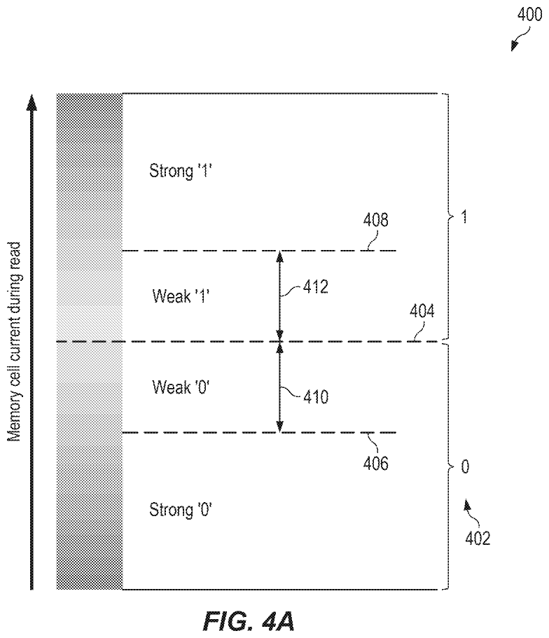

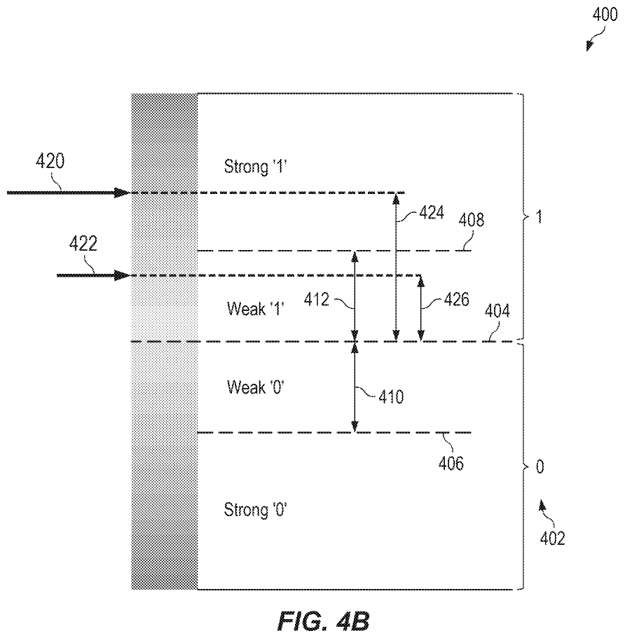

FIGS. 4A and 4B are diagrams associated with a memory cell 400, illustrating example relationships between stored levels of the cell, decision levels, and read margins for different storage states of the cell, where the memory cell is a single-bit cell, according to one or more examples. With reference to FIG. 4A, a memory cell 400 has one of multiple storage states 402 depending on the stored level of the cell. Storage states 402 include first and second storage states, which may correspond to logical states such as logic “0” and logic “1.” A nominal decision level 404 may be used during a nominal read condition to distinguish between the first and second storage states. During a normal read operation, sensing circuitry may compare a measured level of the memory cell, such as a memory cell current during a read operation, to nominal decision level 404 in order to determine the storage state of the memory cell. In the illustrated example, the diagram shows a range of possible stored levels between strong logical states (e.g., strong “0” and strong “1”) and weaker states (e.g., weak “0” and weak “1”) near the decision boundary between the states.

The diagram further illustrates read margin thresholds 406 and 408 associated with read margins of the respective storage states. Read margin threshold 406 is associated with the first storage state, and read margin threshold 408 is associated with the second storage state. Minimum read margin 410 corresponds to the minimum read margin of the first storage state relative to nominal decision level 404, while minimum read margin 412 corresponds to the minimum read margin of the second storage state relative to nominal decision level 404. As is apparent, the margin threshold levels 406 and 408 may define minimum acceptable read margins relative to nominal decision level 404 for the respective storage states. If a stored level of the memory cell approaches nominal decision level 404 such that the corresponding read margin falls below the applicable margin threshold, the corresponding bit may be considered a weak bit.

With respect to FIG. 4B, what is depicted are example first and second stored levels 420 and 422 associated with one of the storage states, namely, the second storage state corresponding to logic “1.” In the illustrated example, first stored level 420 and second stored level 422 are both associated with the same storage state (i.e., logic “1”). First stored level 420 is separated from nominal decision level 404 by a read margin 424. Because read margin 424 is greater than minimum read margin 412 and exceeds read margin threshold 408 associated with the second storage state, first stored level 420 corresponds to a non-weak bit condition. In contrast, second stored level 422 is separated from nominal decision level 404 by read margin 426. Because read margin 426 is less than minimum read margin 412 and falls below read margin threshold 408 associated with the second storage state, second stored level 422 corresponds to a weak bit condition. Thus, two memory cells may correspond to the same storage state while having different read margins relative to the nominal decision level, such that one cell has sufficient margin and another cell may represent a weak bit.

In one or more examples, weak bit detection may be performed by applying a nominal read condition and one or more skewed read conditions to memory cell 400. Under the nominal read condition, nominal decision level 404 is used to determine the storage state of memory cell 400. Under skewed read conditions, sensing parameters may be modified so that the effective stored level of memory cell 400 relative to nominal decision level 404 changes, or equivalently so that the effective sensing boundary relative to the stored level changes. For example, a skewed read condition may be established by adjusting a reference voltage or current of sensing circuitry, or by adjusting bias conditions associated with transistors of memory cell 400. When the stored level has sufficient read margin, such as first stored level 420, the read result may remain unchanged under both the nominal read condition and one or more skewed read conditions, indicating that no weak bit is detected. However, when the stored level has insufficient read margin, such as second stored level 422, application of one or more skewed read conditions may cause the read result to change relative to the nominal read condition, thereby indicating a weak bit.

In one or more examples, the threshold levels relative to nominal decision level 404 may correspond to effective sensing boundaries associated with different skewed read conditions. In such implementations, the skewed read conditions may be used to evaluate the margin of the stored level relative to nominal decision level 404 by determining whether the effective stored level crosses one of the margin thresholds 406 or 408 under a skewed read condition. If the read result changes under the skewed read condition, the corresponding bit may be identified as weak. If the read result does not change, the corresponding bit may be treated as having sufficient read margin.

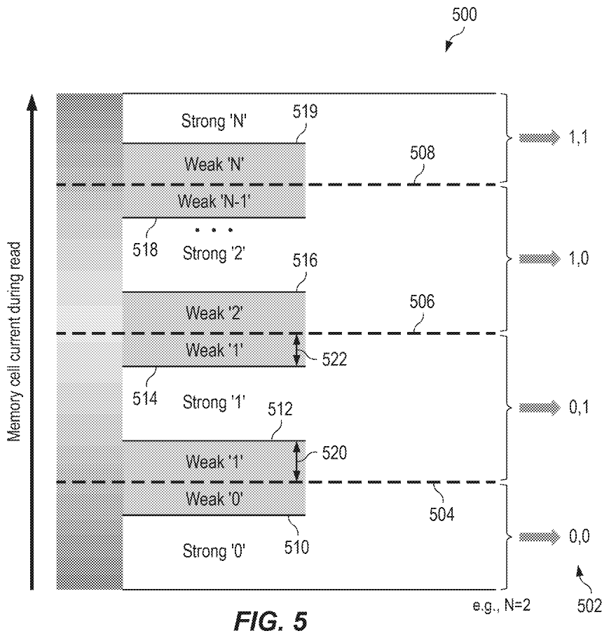

FIG. 5 is a diagram associated with a memory cell 500, illustrating example relationships between stored levels of the cell, decision levels, and read margins for different storage states of the cell, where the memory cell is a multi-bit cell, according to one or more examples. In the illustrated example, memory cell 500 may store multiple bits of information by supporting multiple storage states 502 corresponding to different stored levels of memory cell 500. In the example of FIG. 5, memory cell 500 is a two-bit cell (i.e., N=2), but N may be any suitable integer greater than or equal to two (2). In this example, storage states 502 of memory cell 500 may include a first storage state (0,0), a second storage state (0,1), a third storage state (1,0), and a fourth storage state (1,1). Each storage state may correspond to a different range of stored levels, such as different threshold voltages or memory cell currents measured during a read operation.

Nominal decision levels 504, 506, and 508 may be used to distinguish between the storage states during a nominal read condition. For example, nominal decision level 504 may be used to distinguish between the first storage state (0,0) and the second storage state (0,1), nominal decision level 506 may be used to distinguish between the second storage state (0,1) and the third storage state (1,0), and nominal decision level 508 may be used to distinguish between the third storage state (1,0) and the fourth storage state (1,1). During a read operation, sensing circuitry may compare a measured level of the memory cell to one or more of the nominal decision levels in order to determine which storage state is represented by the stored level.

The diagram further illustrates read margin thresholds associated with minimum acceptable read margins for the respective storage states. A read margin threshold 510 corresponds to a minimum (upper) read margin associated with the first storage state (0,0) relative to nominal decision level 504. A read margin threshold 512 corresponds to a minimum (lower) read margin (e.g., a minimum acceptable read margin 520) associated with the second storage state (0,1) relative to nominal decision level 504, and a read margin threshold 514 corresponds to a minimum (upper) read margin (e.g., a minimum acceptable read margin 522) associated with the second storage state (0,1) relative to nominal decision level 506. A read margin threshold 516 corresponds to a minimum (lower) read margin associated with the third storage state (1,0) relative to nominal decision level 506, and a read margin threshold 518 corresponds to a minimum (upper) read margin associated with the third storage state (1,0) relative to nominal decision level 508. A read margin threshold 519 corresponds to a minimum (lower) read margin associated with the fourth storage state (1,1) relative to nominal decision level 508.

In this manner, each storage state may have one or more associated minimum read margins relative to adjacent nominal decision levels. If the stored level of the memory cell 500 approaches one of the nominal decision levels such that the corresponding read margin falls below the applicable read margin threshold, the corresponding bit or bits stored in memory cell 500 may be considered weak. Such reduced read margin may indicate an increased likelihood that the read result could change under variations in sensing conditions.

In one or more examples, weak bit detection may be performed by applying a nominal read condition and/or one or more skewed read conditions when reading memory cell 500. Under the nominal read condition, nominal decision levels 504, 506, and 508 are used to determine the storage state of memory cell 500. Under skewed read conditions, sensing parameters may be modified so that the effective stored level of memory cell 500 relative to the nominal decision levels changes, or equivalently so that the effective sensing boundaries relative to the stored level change. For example, skewed read conditions may be established by adjusting reference voltages or currents of sense amplifiers or by modifying bias conditions associated with memory cell 500.

When a stored level has sufficient read margin relative to the applicable decision levels, the read result may remain unchanged under both the nominal read condition and one or more skewed read conditions, indicating that the stored state has sufficient margin. However, when the stored level has insufficient read margin relative to one or more decision levels, application of one or more skewed read conditions may cause the read result to change relative to the nominal read condition, thereby indicating a weak bit or weak storage state associated with the multi-bit memory cell.

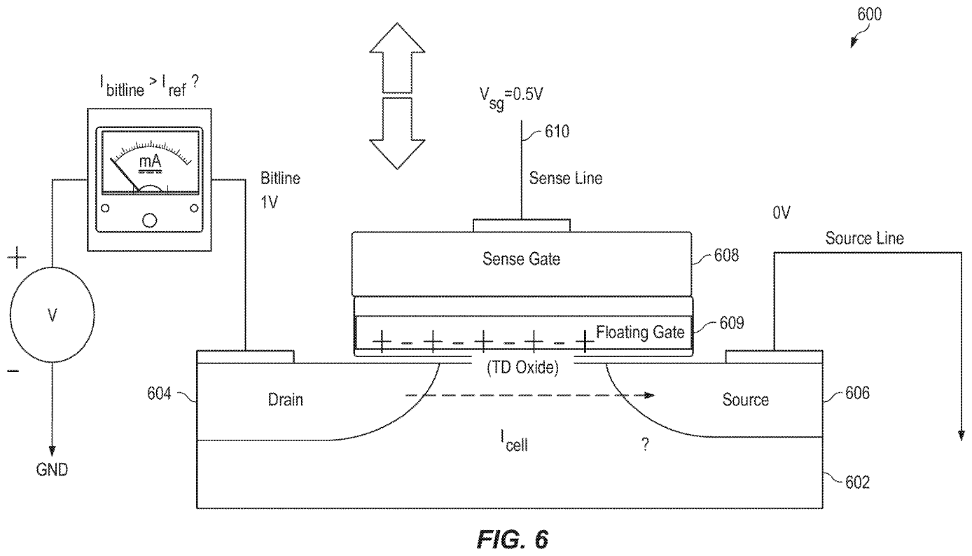

FIG. 6 is a diagram illustrating an example memory cell arrangement 600 that may be used to sense a stored level of a non-volatile memory cell, according to one or more examples. Memory cell arrangement 600 includes a memory cell 602, which in some examples may correspond to a floating-gate transistor used in non-volatile memory such as flash memory.

Memory cell 602 includes a drain 604, a source 606, a sense gate 608, and a floating gate 609. In the illustrated example, drain 604 may be coupled to a bitline through which a read voltage may be applied. A current flowing through memory cell 602 during a read operation may appear as a bitline current I_{bitline}. Source 606 may be coupled to a source line that may be held at or near a reference potential, such as ground.

Sense gate 608 may receive a bias voltage through a sense line 610, which may apply a sense-gate voltage V_{sg} for a read operation. The sense-gate voltage influences conduction of the channel between drain 604 and source 606. As a result, the stored charge on a floating gate of memory cell 602 affects the threshold voltage of the transistor and therefore the current flowing between the drain and source during the read operation. This current may correspond to the cell current I_{cell} flowing through memory cell 602.

During a read operation, sensing circuitry may compare the current flowing on the bitline to a reference current I_{ref}. For example, a determination may be made as to whether the measured bitline current exceeds the reference current I_{ref}. Based on this comparison, the sensing circuitry may determine a storage state associated with memory cell 602.

In one or more examples, sensing conditions for the read operation may be adjusted by modifying sensing parameters, such as the sense-gate voltage V_{sg} applied through sense line 610, the reference current I_{ref}, the source line, or the bitline voltage bias condition, and so on. Adjusting these sensing parameters may change the effective stored level of memory cell 602 relative to the sensing decision boundary used during the read operation. Such adjustments may therefore be used to apply skewed read conditions that allow detection of weak memory cells having reduced read margin.

In one or more examples, sensing conditions used to read memory cell 602 may correspond to a nominal read condition. The sensing conditions may also be intentionally adjusted to establish a skewed read condition, for example by adjusting the sense-gate voltage applied through sense line 610 or by adjusting the reference current I_{ref} used by sensing circuitry. Adjusting these sensing parameters may effectively change the sensed current associated with the stored level of memory cell 602 relative to the decision level defined by the reference current I_{ref}. Such skewed read conditions may therefore be used to evaluate read margin associated with the stored level of the memory cell.

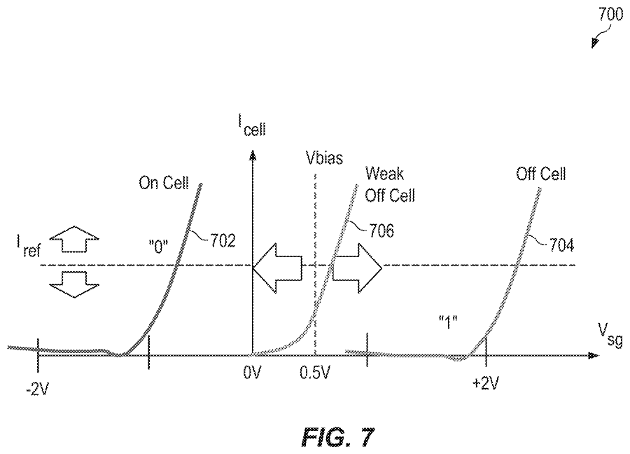

FIG. 7 is a plot 700 illustrating example relationships between a cell current I_{cell} and sense-gate voltage V_{sg} for different storage levels of a memory cell, according to one or more examples. The vertical axis represents the current I_{cell} flowing through the memory cell during a read operation, while the horizontal axis represents the sense-gate voltage V_{sg}.

Plot 700 includes an on-cell curve 702, an off-cell curve 704, and a weak off-cell curve 706. On-cell curve 702 represents behavior of a memory cell programmed to an “on” state (e.g., logic “0”), in which the memory cell conducts relatively large current during a read operation. In contrast, off-cell curve 704 represents behavior of a memory cell programmed to an “off” state (e.g., logic “1”), in which the memory cell conducts relatively little current during the read operation.

The dashed horizontal line in plot 700 represents a reference current I_{ref} used by sensing circuitry to distinguish between storage states. During a read operation, the measured cell current may be compared to the reference current I_{ref}. For example, if the measured cell current exceeds I_{ref}, the sensing circuitry may determine that the cell corresponds to one storage state, whereas if the measured current is below I_{ref}, the sensing circuitry may determine that the cell corresponds to a different storage state.

The difference between the cell current associated with a stored level of the memory cell and the reference current I_{ref} may correspond to a read margin relative to the decision level. A memory cell having a stored level sufficiently separated from the decision level may therefore be considered to have an acceptable read margin. However, when degradation of the memory cell causes the stored level to shift toward the decision level, the read margin may decrease.

Weak off-cell curve 706 represents a degraded or weak memory cell whose stored charge has partially leaked or whose threshold voltage has shifted. As a result, the current of the weak cell may approach the reference current I_{ref}, thereby reducing the read margin between the stored level of the cell and the sensing decision boundary. In such circumstances, the memory cell may correspond to a weak bit, even though the memory cell may still be read correctly under nominal read conditions.

In one or more examples, sensing conditions may be adjusted by modifying parameters such as the sense-gate bias voltage V_{sg} or the reference current I_{ref}. Such adjustments may effectively change the sensed position of the stored level relative to the decision level. If the stored level has sufficient read margin, the read result may remain unchanged under both nominal and adjusted sensing conditions. However, if the stored level has reduced read margin, the read result may change when a skewed read condition is applied, such as by adjusting the sense-gate bias voltage or the reference current. Such behavior may therefore be used to detect weak bits in non-volatile memory.

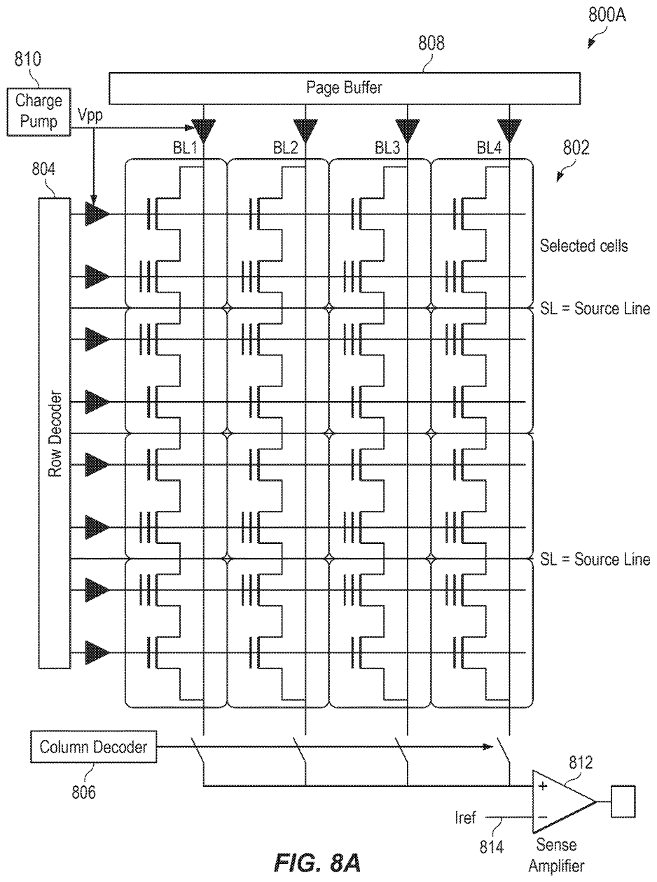

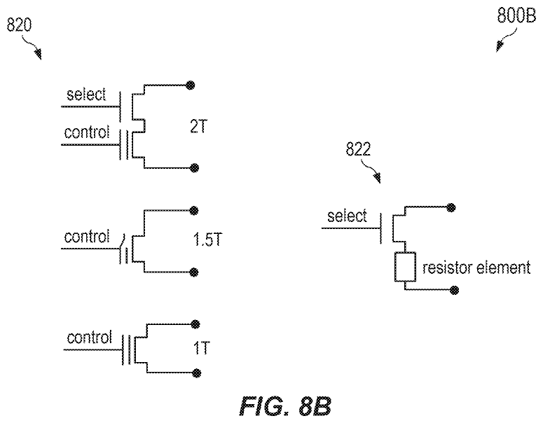

FIG. 8A is a diagram of an example non-volatile memory architecture 800A, such as a NOR-type memory device, according to one or more examples. The memory device includes a memory array 802 comprising a number of memory cells arranged in rows and columns. A row decoder 804 may be configured to select one or more rows of the memory array, while a column decoder 806 may be configured to select one or more columns. A page buffer 808 may be coupled to bitlines (e.g., BL1-BL4) to facilitate programming operations. A charge pump 810 may be provided to generate elevated voltages (e.g., Vpp) used during programming operations.

During a read operation, one or more selected memory cells of memory array 802 may be sensed using a sense amplifier 812, which compares a current associated with the selected memory cell to a reference current I_{ref} 814. In one or more examples, reference current I_{ref} 814 may define a sensing level used to distinguish between storage states of the memory cells. As discussed previously, the read condition may be adjusted by modifying sensing parameters such as reference current I_{ref} 814 or other bias conditions associated with sense amplifier 812. The read condition may also be adjusted by adjusting the voltage that is driven to the gate of the transistor inside the memory cell, or by changing the source line (SL) voltage during read (e.g., FIG. 6). Such adjustments may establish nominal or skewed read conditions that enable detection of weak bits or broken bits based on changes in read results under different sensing conditions.

FIG. 8B is a diagram illustrating example types of non-volatile memory cells 800B in which read conditions may be adjusted by controlling voltages applied to one or more gate terminals or sensing nodes associated with the memory cell. In the illustrated examples, the memory cells include charge-storage-based memory cells 820, such as floating-gate or charge-trap memory cells, and resistance-based memory cells 822, such as resistive random-access memory (RRAM) or phase-change memory (PCM) cells. Although these memory technologies differ in their underlying storage mechanisms, similar techniques may be used to adjust read conditions for purposes such as weak-bit detection. Various other types of non-volatile memory cells may also be used for read condition adjustments, including memory cells with multi-gate transistors, memory cells with additional select transistors, and other variations.

Charge-storage-based memory cells 820 may be implemented using different transistor configurations, such as two-transistor (2T), one-and-a-half-transistor (1.5T), or single-transistor (1T) structures, as illustrated in FIG. 8B. In such implementations, a memory cell may include a floating-gate or charge-trap transistor controlled by a control gate, and in some configurations may also include a select transistor connected in series with the memory cell. The select transistor may be controlled by a select gate that allows the memory cell to be selectively coupled to a bitline during read or write operations. In one or more examples, the effective read condition of the memory cell may be adjusted by modifying voltages applied to one or more of these gate terminals. For example, a gate-to-source voltage or gate bias associated with the storage transistor or with a select transistor in series with the memory cell may be adjusted during a read operation. Adjusting these voltages may change the conduction characteristics of the memory cell during sensing and thereby modify the effective read condition (e.g., to establish a skewed read condition) used to determine the storage state of the cell.

Resistance-based memory cells 822, such as RRAM or phase-change memory cells, generally do not include a floating-gate transistor, but instead include a storage element whose resistance represents the stored data value. In many implementations, the resistive element is coupled in series with a select transistor or access device whose gate may be controlled by a select signal. Similar to charge-storage-based implementations, the read condition of the resistance-based memory cell may be adjusted (e.g., to establish a skewed read condition) by modifying voltages applied to the select transistor, bitline bias conditions, or other sensing circuitry. Such adjustments may influence sensed current or voltage levels and thereby enable detection of weak bits or other degradation conditions.

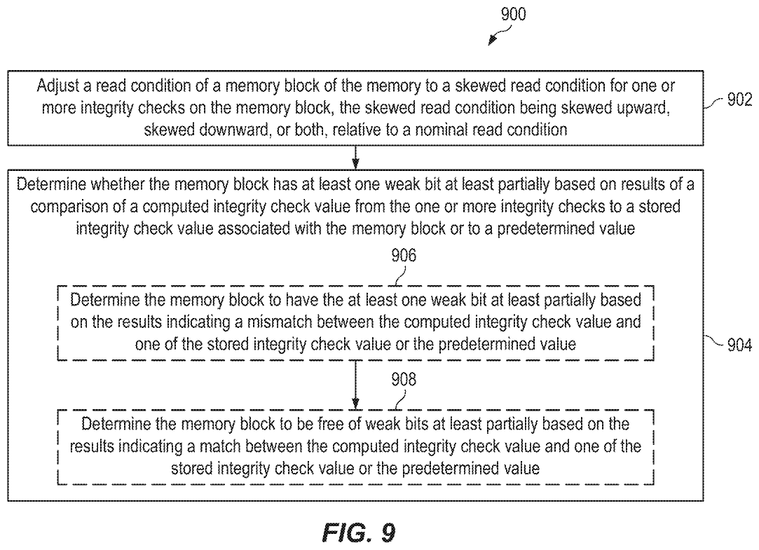

FIG. 9 is a flowchart of a method 900 for weak bit detection, according to one or more examples. In one or more examples, the processing acts of method 900 may be performed by processing device 102 with respect to memory 106 of FIG. 1, while in one or more other examples, the processing acts of method 900 may be performed by processing device 102 with respect to memory 206 of memory device 202 of FIG. 2. In one or more examples, the processing acts of method 900 may be performed by one or more processors executing processor-executable instructions of the processing device, or alternatively, performed by hardware control logic of the processing device.

At an act 902, a read condition of a memory block of the memory is adjusted to a skewed read condition for one or more integrity checks on the memory block. The skewed read condition may be skewed upward, skewed downward, or both, relative to a nominal read condition.

At an act 904, it is determined whether the memory block has at least one weak bit at least partially based on results of a comparison of a computed integrity check value from the one or more integrity checks to a stored integrity check value associated with the memory block or to a predetermined value.

In one or more examples, act 904 may be performed using acts 906 and 908. At an act 908, it is determined that the memory block has the at least one weak bit at least partially based on the results indicating a mismatch between the computed integrity check value and one of the stored integrity check value or the predetermined value, and at an act 908, it is determined that the memory block is free of weak bits at least partially based on the results indicating a match between the computed integrity check value and one of the stored integrity check value or the predetermined value.

In one or more examples, a weak bit corresponds to a stored level of a non-volatile memory cell having a read margin that is less than a minimum acceptable read margin relative to one or more decision levels that define a storage state of the non-volatile memory cell.

In one or more examples of act 902, a reference voltage or current of respective sense amplifiers of the non-volatile memory cells is adjusted, at least by a determined amount, relative to a nominal read reference. In one or more other examples of act 902, a source-to-gate voltage of respective transistors associated with the non-volatile memory cells is adjusted, at least by a determined amount, relative to a nominal read reference.

In one or more examples of act 902, the read condition of the memory block is adjusted to the skewed read condition by setting one or more values of one or more configuration registers used to adjust the read condition of the non-volatile memory cells of the memory block relative to the nominal read condition. In one or more examples of act 902, the read condition of the memory block is adjusted to the skewed read condition by adjusting a signal applied to one or more inputs of the memory to adjust the read condition of the non-volatile memory cells relative to the nominal read condition.

In one or more examples, method 900 further includes providing an indication that a weak bit has been detected. In one or more examples, the indication may be provided through one or more outputs or interfaces of the processing device or memory device, such as a status register, interrupt signal, debug interface, system bus interface, or communication interface, thereby allowing software, firmware, or an external system to detect the weak-bit condition.

In one or more examples, method 900 further includes performing one or more data recovery operations for the non-volatile memory cells of the memory block at least partially responsive to determining the memory block to have the at least one weak bit. In one or more examples, the one or more data recovery operations include reprogramming data in the non-volatile memory cells of the memory block to increase read reliability of the memory block; remapping data of the memory block to other available non-volatile memory cells of the memory to increase the read reliability of the memory block; and/or identifying and applying an updated nominal read condition for subsequent reads of the memory block to increase the read reliability of the memory block.

In one or more examples, the one or more integrity checks comprise at least one of a CRC operation or an EDAC operation, such as an ECC operation. For example, ECC operations may be performed on each data word during multiple read operations executed under different read conditions, such as nominal and skewed read conditions. For each read operation, an ECC result (e.g., pass/fail, error detection, or correction status) may be generated for each data word. By comparing ECC results for corresponding data words across the different read conditions, the control circuitry may identify, for example, inconsistencies indicative of reduced read margin. Such inconsistencies may be used to detect weak bits associated with one or more memory cells corresponding to the affected data word.

In one or more other examples, the integrity checks may comprise a syndrome-based error detection operation. Here, a syndrome is computed based on data of the memory block, including any stored integrity check value associated with the memory block. The computed syndrome may represent an integrity check value that is evaluated relative to a predetermined value, such as zero (0), where a zero-valued syndrome indicates that the data satisfies the integrity check condition and a non-zero syndrome indicates that an error is present. For example, the control circuitry may determine the memory block to have the at least one weak bit at least partially based on results indicating that the computed syndrome does not match the predetermined value (e.g., is non-zero), or may determine the memory block to be free of weak bits at least partially based on results indicating that the computed syndrome matches the predetermined value (e.g., is equal to zero).

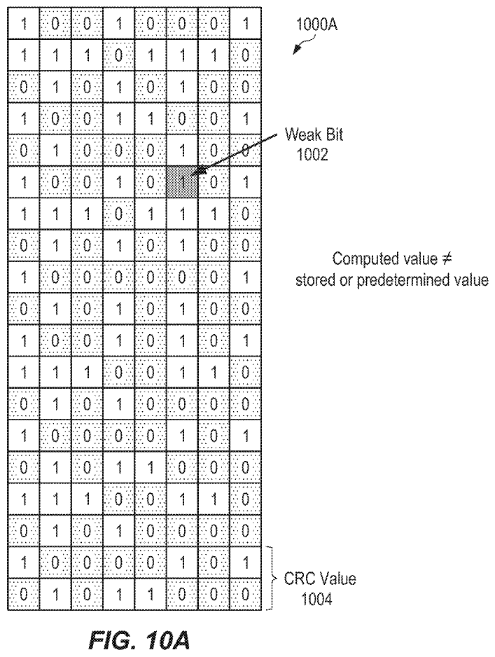

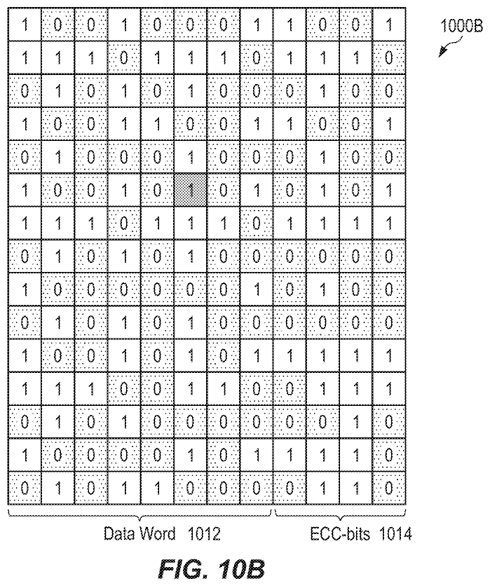

FIG. 10A is a diagram illustrating an example memory block 1000A used for weak bit detection based on integrity checks, according to one or more examples. In one or more examples, memory block 1000A may be processed in relation to method 900 of FIG. 9. Memory block 1000A includes a number of memory cells storing corresponding bit values. Each element shown in the array corresponds to a bit value (e.g., “0” or “1”) obtained from a respective memory cell when memory block 1000A is read or scanned, where each bit value corresponds to a stored state of a respective non-volatile memory cell. Memory block 1000A further includes an integrity check value 1004, such as a CRC value, associated with the data bits of memory block 1000A. The integrity check value 1004 may be used to verify correctness of the data read from memory block 1000A and to assist in detecting the presence of weak bits when memory block 1000A is evaluated under one or more skewed read conditions (e.g., as described in method 900 of FIG. 9). In the illustrated example, one of the bit locations corresponds to a weak bit 1002, which may produce an unreliable read value under certain read conditions due to reduced read margin of the associated memory cell.

FIG. 10B is a diagram illustrating an example memory block 1000B that includes stored data and associated error correction information, according to one or more examples. In one or more examples, memory block 1000B may be processed in relation to method 900 of FIG. 9. Similar to memory block 1000A, memory block 1000B includes a number of memory cells storing corresponding bit values (e.g., logic “0” and “1”), where each bit value corresponds to a stored state of a respective non-volatile memory cell. In the illustrated example, the memory block includes one or more data words, including a data word 1012, and associated ECC bits 1014. ECC bits 1014 may be generated based on data word 1012 and stored within memory block 1000B to enable detection and correction of errors during read operations. In one or more examples, ECC bits 1014 may be evaluated in a manner similar to integrity check values, such that results of read operations performed under nominal or skewed read conditions may be used in conjunction with ECC bits 1014 to detect weak bits or other memory degradation conditions within memory block 1000B. In one or more examples, ECC may be performed for each read of a respective one of the data words of memory block 1000B, that is, ECC may be computed and checked per data word under a skewed read condition for the detection of weak bits.

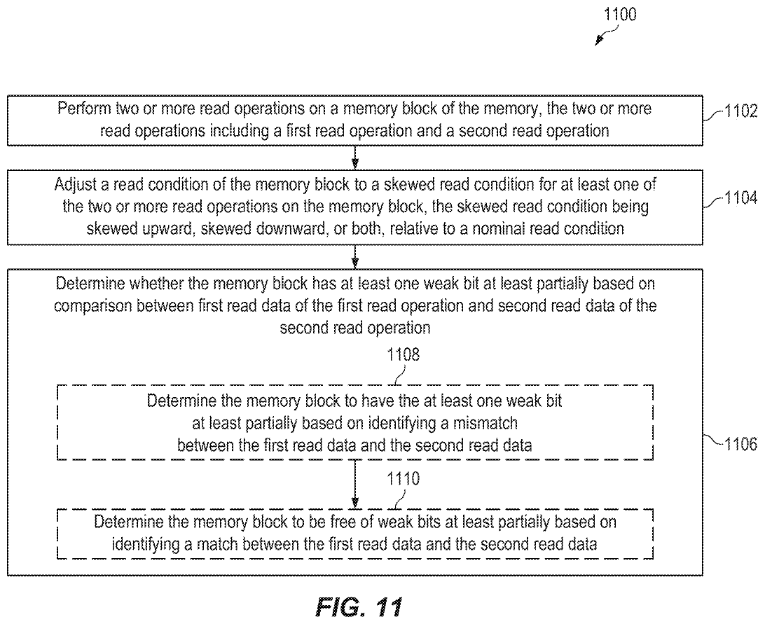

FIG. 11 is a flowchart of a method 1100 for weak bit detection, according to one or more examples. In one or more examples, the processing acts of method 1100 may be performed by processing device 102 with respect to memory 106 of FIG. 1, while in one or more other examples, the processing acts of method 1100 may be performed by processing device 102 with respect to memory 206 of memory device 202 of FIG. 2. In one or more examples, the processing acts of method 1100 may be performed by one or more processors executing processor-executable instructions of the processing device, or alternatively, performed by hardware control logic of the processing device.

At an act 1102, two or more read operations are performed on a memory block of the memory. The two or more read operations include at least a first read operation and a second read operation.

At an act 1104, a read condition of a memory block of the memory is adjusted to a skewed read condition for at least one of the two or more read operations on the memory block. The skewed read condition may be skewed upward, skewed downward, or both, relative to a nominal read condition.

At an act 1106, it is determined whether the memory block has at least one weak bit at least partially based on (e.g., results of) comparison between first read data of the first read operation and second read data of the second read operation.

In one or more examples, act 1106 may be performed using acts 1108 and 1110. At an act 1108, it is determined that the memory block has the at least one weak bit at least partially based on identifying a mismatch between the first read data and the second read data. At an act 1110, it is determined that the memory block is free of weak bits at least partially based on identifying a match between the first read data and the second read data.

In one or more examples, a weak bit corresponds to a stored level of a non-volatile memory cell having a read margin that is less than a minimum acceptable read margin relative to one or more decision levels that define a storage state of the non-volatile memory cell.

In one or more examples, one of the first read operation or the second read operation use the skewed read condition to read the memory block, and the other one of the first read operation or the second read operation use the nominal read condition to read the memory block. In one or more other examples, the first read operation uses a first skewed read condition (e.g., a downward skewed read condition) to read the memory block and the second read operation uses a second skewed read condition (e.g., an upward skewed read condition) to read the memory block.

In one or more examples, method 1100 further includes identifying at least one weak bit location of the at least one weak bit of the memory block at least partially based on bit differences between corresponding bits of the first read data and the second read data.

In one or more examples, one of the first read operation or the second read operation use the skewed read condition to read the memory block, and the other one of the first read operation or the second read operation use the nominal read condition to read the memory block. In one or more other examples, the first read operation uses a first skewed read condition (e.g., a downward skewed read condition) to read the memory block and the second read operation uses a second skewed read condition (e.g., an upward skewed read condition) to read the memory block.

In one or more examples of act 1104, a reference voltage or current of respective sense amplifiers of the non-volatile memory cells is adjusted, at least by a determined amount, relative to a nominal read reference. In one or more other examples of act 1104, a source-to-gate voltage of respective transistors associated with the non-volatile memory cells is adjusted, at least by a determined amount, relative to a nominal read reference.

In one or more examples of act 1104, the read condition of the memory block is adjusted to the skewed read condition by setting one or more values of one or more configuration registers used to adjust the read condition of the non-volatile memory cells of the memory block relative to the nominal read condition. In one or more examples of act 1104, the read condition of the memory block is adjusted to the skewed read condition by adjusting a signal applied to one or more inputs of the memory to adjust the read condition of the non-volatile memory cells relative to the nominal read condition.

In one or more examples, method 1100 further includes providing an indication that a weak bit has been detected. In one or more examples, the indication may be provided through one or more outputs or interfaces of the processing device or memory device, such as a status register, interrupt signal, debug interface, system bus interface, or communication interface, thereby allowing software, firmware, or an external system to detect the weak-bit condition.

In one or more examples, method 1100 further includes performing one or more data recovery operations for the non-volatile memory cells of the memory block at least partially responsive to determining the memory block to have the at least one weak bit. In one or more examples, the one or more data recovery operations include reprogramming data in the non-volatile memory cells of the memory block to increase read reliability of the memory block; remapping data of the memory block to other available non-volatile memory cells of the memory to increase the read reliability of the memory block; and/or identifying and applying an updated nominal read condition for subsequent reads of the memory block to increase the read reliability of the memory block.

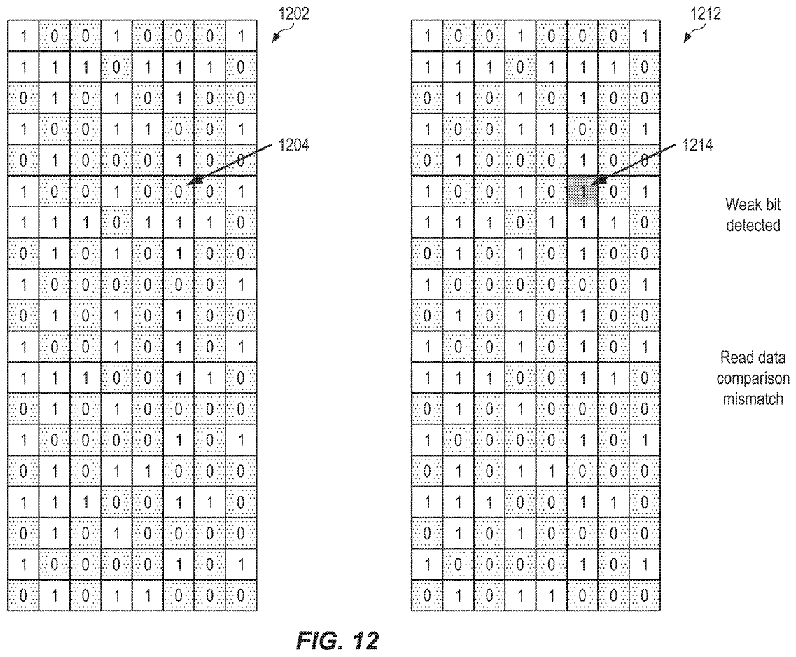

FIG. 12 is a diagram illustrating example memory blocks used for weak bit detection based on read data comparisons, according to one or more examples. In one or more examples, the memory blocks may be processed in relation to method 1100 of FIG. 11.

In the illustrated example, a first memory block 1202 and a second memory block 1212 each include a plurality of bit values arranged as one or more data words, representing data read from corresponding non-volatile memory cells. Each element in the arrays corresponds to a bit value (e.g., “0” or “1”) obtained from a respective memory cell when the memory block is read or scanned. Each bit value corresponds to a stored state of a respective non-volatile memory cell within each of memory block 1202 and memory block 1212.

In one or more examples, first and second memory blocks 1202 and 1212 represent results of multiple read operations performed on the same memory block under different read conditions, such as a nominal read condition and a skewed read condition, or two different skewed read conditions. Under ideal conditions, the read data from the multiple read operations would be identical. In the illustrated example, however, a bit 1204 associated with a memory cell having reduced read margin may produce different read results between the read operations. As shown, a corresponding bit 1214 in second memory block 1212 differs from the bit value of bit 1204 in first memory block 1202, which indicates detection of a weak bit associated with the corresponding memory cell.

In one or more examples, the read data comparisons described above may be performed on a data word-by-data word basis. For example, corresponding data words obtained from multiple read operations under different read conditions may be compared to determine whether any bit values differ between the data words. Detection of a mismatch within a particular data word may indicate the presence of at least one weak bit associated with one or more memory cells corresponding to that data word. This data word-based comparison approach may be distinguished from comparisons performed across an entire memory block including multiple data words, and may help to facilitate a localized identification of weak bit conditions within the memory. Note further, for these implementations, that ECC correction can be performed on every read of a data word.

Thus, the control circuitry may compare the read data obtained from the multiple read operations and identify bit differences between corresponding bit locations of the memory blocks. Based at least partially on detection of such a mismatch, the control circuitry may determine that the memory block contains at least one weak bit, and may optionally identify the location of the weak bit within the memory block.

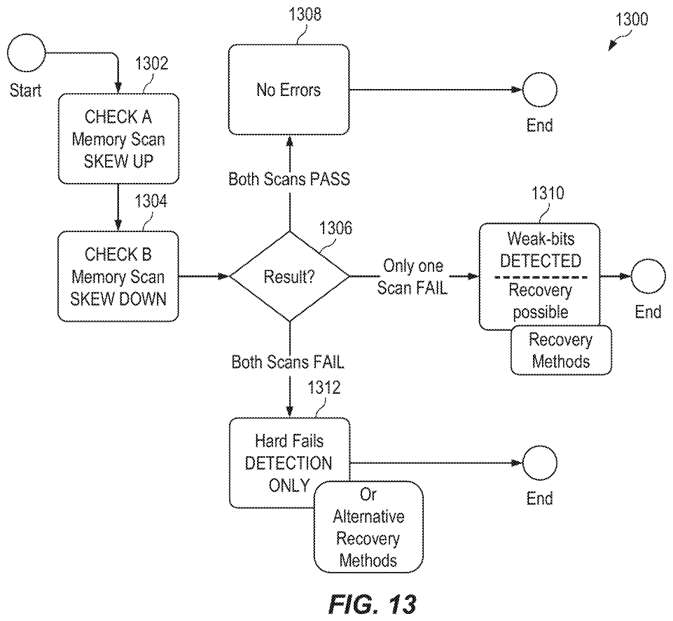

FIG. 13 is a flowchart of an example method 1300 for detecting weak bits in non-volatile memory using memory scans performed under different read conditions, according to one or more examples. In one or more examples, the processing acts of method 1300 may be performed by processing device 102 with respect to memory 106 of FIG. 1, while in one or more other examples, the processing acts of method 1300 may be performed by processing device 102 with respect to memory 206 of memory device 202 of FIG. 2. In one or more examples, the processing acts of method 1300 may be performed by one or more processors executing processor-executable instructions of the processing device, or alternatively, performed by hardware control logic of the processing device.

At an act 1302, a first memory scan of a memory block using a first skewed read condition is performed (“CHECK A”). In one or more examples, this scan may correspond to a skew-up read condition in which sensing parameters of the memory are adjusted relative to a nominal read condition.

At an act 1304, a second memory scan of the memory block using a second skewed read condition is performed (“CHECK B”). In one or more examples, the second skewed read condition may correspond to a skew-down read condition relative to the nominal read condition.

At an act 1306, the results of the first and second scans are evaluated. In one or more examples, each scan may involve an integrity check operation (e.g., using method 900 of FIG. 9) (e.g., CRC or error detection code) on data read from the memory block; based on the integrity check results, it is determined whether the scans pass or fail. In one or more other examples, each scan may involve two or more read operations (e.g., using method 1100 of FIG. 11) on data from the memory block; based on read comparison results, it is determined whether the scans pass or fail. In one or more additional examples, each “scan” may actually be just a read of a data word involving ECC correction.

If both scans pass, the process proceeds to act 1308, indicating that no errors or weak bits are detected in the memory block.

If one scan passes and the other scan fails, the process proceeds to act 1310, indicating detection of one or more weak bits. In one or more examples, recovery operations may be performed, such as refreshing or reprogramming the memory cells associated with the weak bits.

If both scans fail, the process proceeds to act 1312, indicating a hard failure condition, such as corruption of the data or the presence of multiple weak bits affecting both polarities of stored data. In one or more other examples, alternative recovery operations are performed with respect to the memory cells associated with the weak bits.

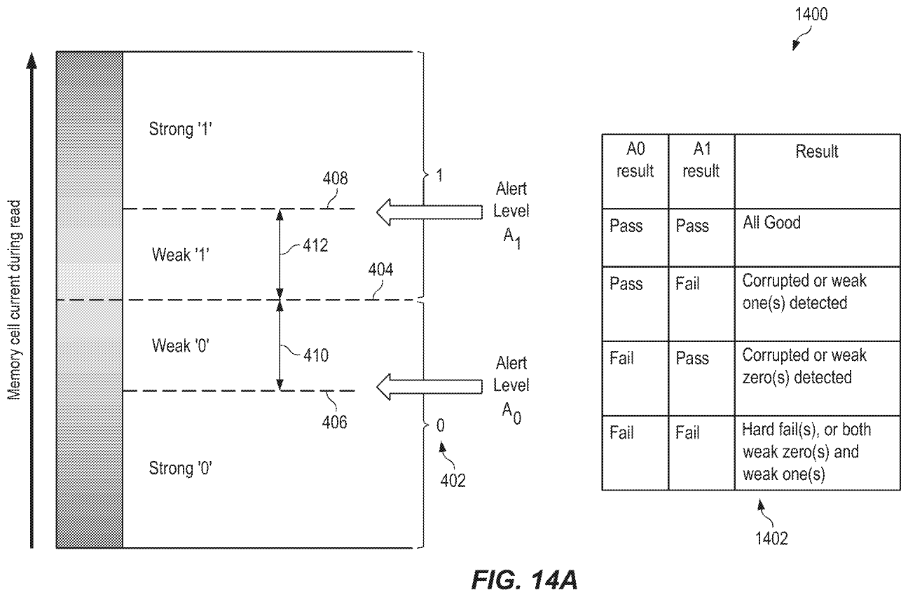

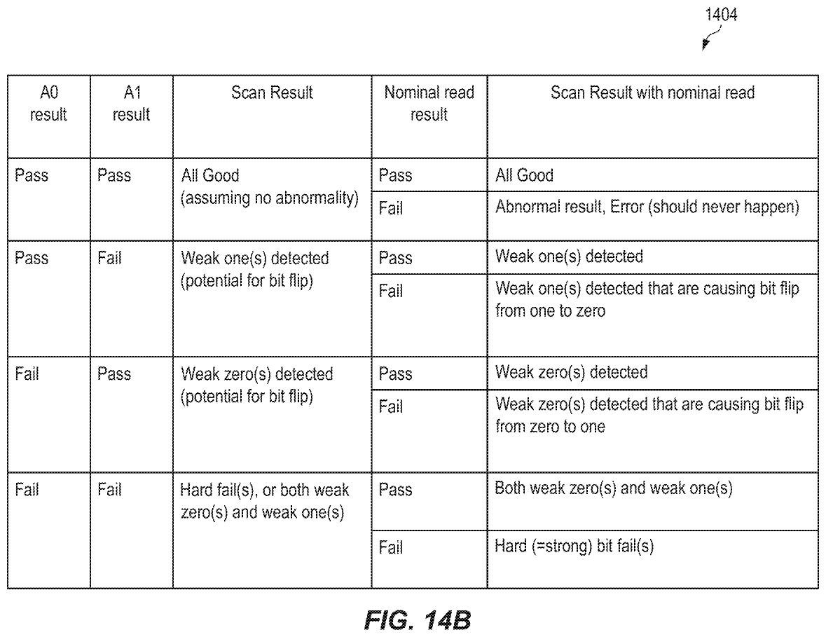

FIG. 14A is a diagram illustrating example sensing margins and alert levels of a memory cell 1400 which may be used in the scans of method 1300 of FIG. 13. The depiction of memory cell 1400 of FIG. 14A is substantially the same as memory cell 400 of FIG. 4A. The vertical axis represents memory cell current during a read operation, which corresponds to the stored level of a memory cell relative to sensing decision levels.

In the illustrated example, the diagram shows a range of possible stored levels between strong logical states (e.g., strong “1” and strong “0”) and weaker states near the decision boundary between the states. The diagram further illustrates alert levels A₀ and A₁, which correspond to skewed read conditions which may be applied during the memory scans performed at acts 1302 and 1304 of FIG. 13. In one or more examples, Alert level A₁ corresponds to a skewed read condition that is configured to detect weak “1” states, while Alert level A₀ corresponds to a skewed read condition that is configured to detect weak “0” states.

In FIG. 14A, a table 1402 of possible scan results corresponding to the two scans performed in FIG. 13 is also provided. When the scan using alert level A₀ and the scan using alert level A₁ both pass, the data is considered valid and the memory block is determined to have no weak bits. When one scan passes and the other scan fails, the system identifies a weak bit corresponding to the polarity associated with the failing scan (e.g., weak “1” or weak “0”). When both scans fail, the result may indicate a hard failure, such as data corruption or multiple weak bits affecting both polarities. In one or more examples, a new scan at the nominal read condition may be performed to differentiate between bit-flip, or weak-bits with both polarities.

FIG. 14B is a table 1404 illustrating example relationships between results of scans performed under different read conditions and corresponding outcomes when compared with a nominal read result, according to one or more examples. Table 1404 of FIG. 14B includes more specific details as compared to table 1402 of FIG. 14A. For example, table 1404 summarizes how scan results obtained using multiple skewed read conditions (e.g., Alert Level A₀ and Alert level A₁) may be interpreted in conjunction with a nominal read operation to distinguish between normal operation, weak bit conditions, and hard failure conditions. As indicated in the example, combinations of scan results and nominal read results may be used to identify weak bits that have not yet caused functional errors, as well as weak bits that are already causing bit flips or other abnormal behavior. In some cases, agreement or disagreement between scan results and nominal read results may provide additional insight into the type and severity of memory degradation.

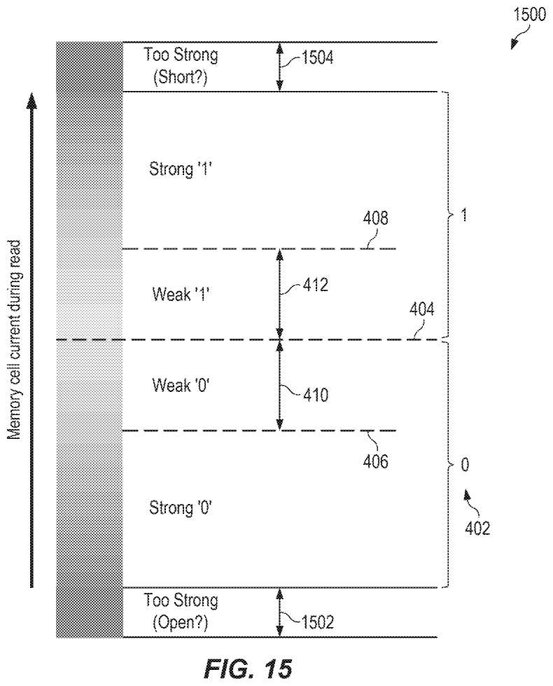

FIG. 15 is a diagram illustrating example relationships between stored levels of a memory cell 1500 and read margins for detecting weak bits and broken bits in non-volatile memory, according to one or more examples. The depiction of memory cell 1500 in FIG. 15 is substantially the same as memory cell 400 previously described in relation to FIG. 4A, in which stored levels of the memory cell are evaluated relative to one or more decision levels and associated read margins. As described previously with respect to FIG. 4A, stored levels that fall within defined read margin ranges relative to the decision levels correspond to valid storage states of the memory cell, while stored levels approaching the decision levels may correspond to weak bits having reduced read margin.

In FIG. 15, additional upper-limit regions can be used to detect abnormal or broken memory cells. For example, a too-strong region 1502 associated with the logical “0” storage state may correspond to a memory cell exhibiting excessively strong conduction during a read operation. Such behavior may occur in cases, such as an “open” memory cell, or other defect resulting in abnormal current flow. Similarly, a too-strong region 1504 associated with the logical “1” storage state may correspond to a memory cell exhibiting abnormal behavior, such as a “shorted” memory cell or other defect, resulting in stored levels outside an expected operating range.

In one or more examples, detection of such abnormal conditions may be performed by applying adjusted or skewed read conditions that extend beyond those used for weak-bit detection. For example, sensing parameters of the memory may be adjusted so that the effective sensing condition shifts relative to the nominal decision level, thereby allowing the system to probe whether the stored level of memory cell 1500 falls within upper-limit regions 1502 or 1504. If the stored level enters one of these regions under the adjusted read condition, the control circuitry may determine that the corresponding memory cell exhibits a broken bit condition, such as a shorted cell, open cell, or other hard failure.

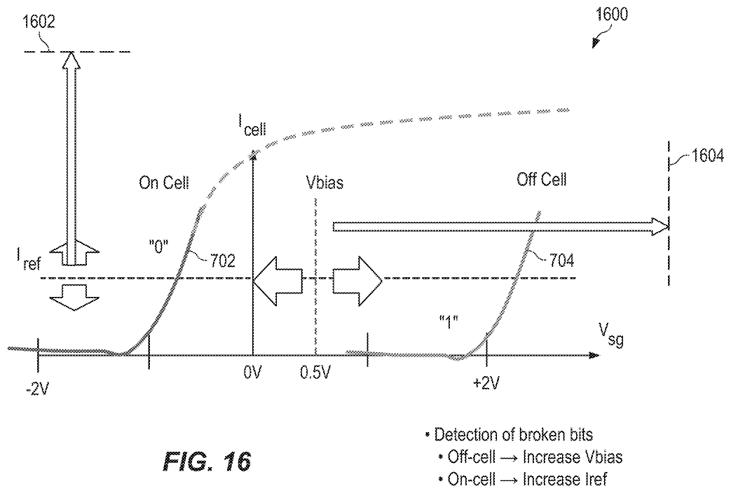

FIG. 16 is a plot 1600 illustrating example sensing conditions used to detect broken bits in a memory cell, according to one or more examples. The diagram shows relationships between cell current I_{cell} and sense-gate voltage V_{sg} for different operating conditions of the memory cell. On-cell curve 702 corresponds to an on-cell condition (e.g., logic “0”), while curve 704 corresponds to an off-cell condition (e.g., logic “1”).

In one or more examples, detection of broken bits may be performed by adjusting sensing parameters to establish skewed read conditions that extend beyond nominal read conditions. For example, an increased reference current setting 1602 may be used to detect abnormal behavior of on-cells. Increasing the reference current shifts the effective sensing threshold so that cells exhibiting excessively strong conduction, such as shorted or otherwise defective cells, produce detectable read results. Similarly, an increased voltage bias setting 1604 may be applied to modify the sensing conditions used for detecting off-cells. Increasing the bias voltage applied to the sense gate may shift the sensed operating point of the memory cell, allowing detection of abnormal off-cell behavior such as open or otherwise defective cells.

In one or more examples, the sensing adjustments illustrated in FIG. 16 may be used to implement the detection of upper-limit regions described in FIG. 15. Accordingly, by applying skewed read conditions such as increased reference current or increased bias voltage, the control circuitry may identify broken bits associated with abnormal conduction characteristics of memory cells, in addition to detecting weak bits associated with reduced read margin.

As discussed earlier above, if it is determined that a memory block has at least one weak bit, one or more data recovery operations for the non-volatile memory cells may be performed. In one or more examples, the one or more data recovery operations include reprogramming data in the non-volatile memory cells of the memory block to increase read reliability of the memory block; remapping data of the memory block to other available non-volatile memory cells of the memory to increase the read reliability of the memory block; and/or identifying and applying an updated nominal read condition for subsequent reads of the memory block to increase the read reliability of the memory block. In one or more examples, a “safe start” for memory with weak bits may be implemented.

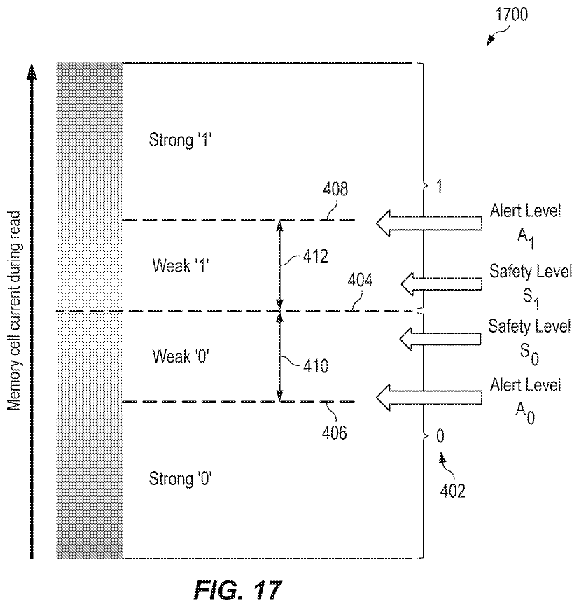

FIG. 17 is a diagram illustrating example relationships between stored levels of a memory cell 1700 and conditions associated with a safe start for weak bits, according to one or more examples. The depiction of memory cell 1700 in FIG. 17 is substantially the same as memory cell 400 previously described in relation to FIG. 4A, in which stored levels of the memory cell are evaluated relative to one or more decision levels and associated read margins. As described previously with respect to FIG. 4A, stored levels that fall within defined read margin ranges relative to the decision levels correspond to valid storage states of the memory cell, while stored levels approaching the decision levels may correspond to weak bits having reduced read margin.

Safe start can be attempted using at least one of the following approaches. In a first approach, a simple technique is employed using error detection codes. In this approach, an integrity check (e.g., CRC or other EDC) with normal read condition may be performed. If it passes, the application may be started with an indication that weak bits were detected. If it fails, then the system may be placed in a safe state (e.g., the system passes, but does not allow the execution of code from faulty memory).

In a second approach, added safety level checks are provided. In this approach, additional CRC checks with Safety levels S₀ and S₁ (FIG. 17) are performed and the application is allowed to run if both safety levels pass. Here, “too weak” is not allowed.

In a third approach, a technique is employed without use of error detection codes. In this approach, weak-bit detection is performed simply by checking that bits match when read with both Alert levels A₀ and A₁. If readouts with the Alert levels A₀ and A₁ do not match (i.e., weak bits are detected), then it is possible to do a second readout using Safety levels S₀ and S₁. If readouts with Safety Levels S₀ and S₁ match, then code execution is allowed, but the application is alerted to indicate weak bits.

In other approaches, more complex sweeps can be performed to search a safe read level for weak bits, looking for a window where the CRC passes, and allowing operation using a setting in the middle of the passing window with safety margin criteria.

In view of the foregoing examples, techniques described herein provide mechanisms for detecting weak bits and other abnormal conditions in non-volatile memory by evaluating memory data under modified or skewed read conditions. By intentionally adjusting read conditions relative to nominal sensing conditions, stored levels of memory cells may be evaluated to determine whether the memory cells exhibit reduced read margins, weak initial programming, or other degradation conditions before a functional failure occurs. In some implementations, such detection may be performed using integrity-check scans, comparisons of read data obtained under different read conditions, or combinations thereof. The techniques may therefore provide early indication of charge loss or memory degradation and may enable corrective actions such as refreshing or reprogramming affected memory cells. In one or more examples, the disclosed techniques may improve functional safety of systems utilizing non-volatile memory, while requiring little or no additional silicon area and without imposing practical limits on the number of weak bits that may be detected. The techniques may also operate in conjunction with existing integrity-check mechanisms, such as CRC or error detection and correction circuitry, and may be particularly beneficial in safety-critical environments, including automotive or other high-reliability computing systems.

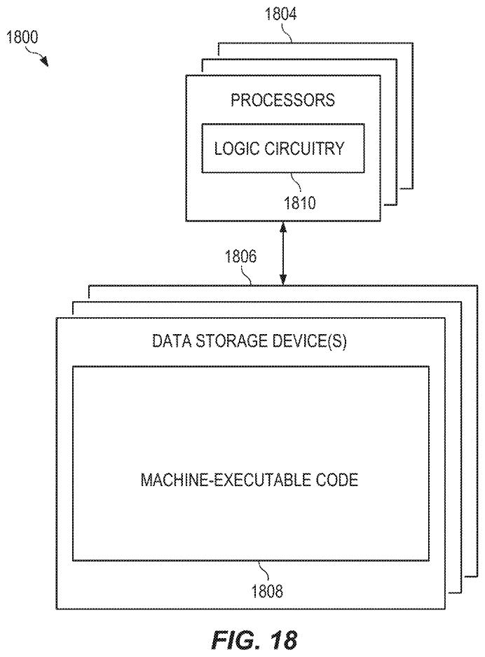

It will be appreciated by those of ordinary skill in the art that functional elements of examples disclosed herein (e.g., functions, operations, acts, processes, and/or methods) may be implemented in any suitable hardware, software, firmware, or combinations thereof. FIG. 18 illustrates non-limiting examples of implementations of functional elements disclosed herein. In some examples, some or all portions of the functional elements disclosed herein may be performed by hardware specially implemented for carrying out the functional elements.

FIG. 18 is a block diagram of circuitry 1800 that, in some examples, may be used to implement various functions, operations, acts, processes, and/or methods disclosed herein. Circuitry 1800 includes one or more processors 1804 (sometimes referred to herein as “processor 1804”) operably coupled to one or more data storage devices (sometimes referred to herein as “storage 1806”). Storage 1806 includes machine-executable code 1808 stored thereon, and processor 1804 includes a logic circuitry 1810. Machine-executable code 1808 includes information describing functional elements that may be implemented by (e.g., performed by) logic circuitry 1810. Logic circuitry 1810 is adapted to implement (e.g., perform) the functional elements described by machine-executable code 1808. Circuitry 1800, when executing the functional elements described by machine-executable code 1808, should be considered as special purpose hardware for carrying out functional elements disclosed herein. In some examples, processor 1804 may perform the functional elements described by machine-executable code 1808 sequentially, concurrently (e.g., on one or more different hardware platforms), or in one or more parallel process streams.

When implemented by logic circuitry 1810 of processor 1804, machine-executable code 1808 adapts processor 1804 to perform operations of examples disclosed herein. In some examples, machine-executable code 1808 may adapt processor 1804 to perform at least a portion or a totality of methods or processes described herein (e.g., methods or processing acts associated with FIGS. 9, 11, and 13 including features associated with other related figures).

Processor 1804 may include a general-purpose processor, a special purpose processor, a CPU, a microcontroller, a programmable logic controller (PLC), a DSP, an application specific integrated circuit (ASIC), a field-programmable gate array (FPGA) or other programmable logic device, discrete gate or transistor logic, discrete hardware components, other programmable device, or any combination thereof designed to perform the functions disclosed herein. A general-purpose computer including a processor is considered a special-purpose computer while the general-purpose computer executes functional elements corresponding to machine-executable code 1808 (e.g., software code, firmware code, hardware descriptions) related to examples of the disclosure. It is noted that a general-purpose processor (may also be referred to herein as a host processor or simply a host) may be a microprocessor, but in the alternative, processor 1804 may include any conventional processor, controller, microcontroller, or state machine. Processor 1804 may also be implemented as a combination of computing devices, such as a combination of a DSP and a microprocessor, a plurality of microprocessors, one or more microprocessors in conjunction with a DSP core, or any other such configuration.

In some examples, storage 1806 includes volatile data storage (e.g., RAM), non-volatile data storage (e.g., Flash memory, a hard disc drive, a solid-state drive, erasable programmable read-only memory (EPROM), etc.). In some examples, processor 1804 and storage 1806 may be implemented into a single device (e.g., a semiconductor device product, a system on chip (SOC), etc.). In some examples, processor 1804 and storage 1806 may be implemented into separate devices.

In some examples, machine-executable code 1808 may include computer-readable instructions (e.g., software code, firmware code). By way of non-limiting example, the computer-readable instructions may be stored by storage 1806, accessed directly by processor 1804, and executed by processor 1804 using at least logic circuitry 1810. Also by way of non-limiting example, the computer-readable instructions may be stored on storage 1806, transferred to a memory device (not shown) for execution, and executed by processor 1804 using at least logic circuitry 1810. Accordingly, in some examples, logic circuitry 1810 includes electrically configurable logic circuitry 1810.

In some examples, machine-executable code 1808 may describe hardware (e.g., circuitry) to be implemented in logic circuitry 1810 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, Verilog, SystemVerilog, and/or very large-scale integration (VLSI) hardware description language (VHDL) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuitries (e.g., gates, flip-flops, registers, without limitation) of logic circuitry 1810 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples, machine-executable code 1808 may include an HDL, an RTL, a GL description, a mask level description, other hardware description, or any combination thereof.

In examples where machine-executable code 1808 includes a hardware description (at any level of abstraction), a system (not shown, but including storage 1806) may implement the hardware description described by machine-executable code 1808. By way of non-limiting example, processor 1804 may include a programmable logic device (e.g., an FPGA or a PLC) and logic circuitry 1810 may be electrically controlled to implement circuitry corresponding to the hardware description into logic circuitry 1810. Also by way of non-limiting example, logic circuitry 1810 may include hard-wired logic manufactured by a manufacturing system (not shown, but including storage 1806) according to the hardware description of machine-executable code 1808.

Regardless of whether machine-executable code 1808 includes computer-readable instructions or a hardware description, logic circuitry 1810 is adapted to perform the functional elements described by machine-executable code 1808 when implementing the functional elements of machine-executable code 1808. It is noted that although a hardware description may not directly describe functional elements, a hardware description indirectly describes functional elements that the hardware elements described by the hardware description are capable of performing.

As used in the disclosure, the terms “module” or “component” may refer to specific hardware implementations to perform the actions of the module or component and/or software objects or software routines that may be stored on and/or executed by general purpose hardware (e.g., computer-readable media, processing devices, etc.) of the computing system. In some examples, the different components, modules, engines, and services described in the disclosure may be implemented as objects or processes that execute on the computing system (e.g., as separate threads). While some of the system and methods described in the disclosure are generally described as being implemented in software (stored on and/or executed by general purpose hardware), specific hardware implementations or a combination of software and specific hardware implementations are also possible and contemplated.

As used in the disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc. ,” or “one or more of A, B, and C, etc. ,” is used, in general such a construction is intended to include A alone, B alone, C alone, A and B together, A and C together, B and C together, or A, B, and C together, etc.

Any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

A non-exhaustive, non-limiting list of examples follows. Not each of the examples listed below is explicitly and individually indicated as being combinable with all others of the examples listed below and examples discussed above. It is intended, however, that these examples are combinable with all other examples unless it would be apparent to one of ordinary skill in the art that the examples are not combinable.

Example 1: A device comprising: control circuitry to perform operations with respect to memory accessible to the control circuitry, the memory comprising non-volatile memory cells and organized into one or more memory blocks, each memory block comprising one or more data words, the control circuitry to: adjust a read condition of a memory block of the memory to a skewed read condition for one or more integrity checks on the memory block, the skewed read condition being skewed upward, skewed downward, or both, relative to a nominal read condition; and determine whether the memory block has at least one weak bit at least partially based on results of a comparison of a computed integrity check value from the one or more integrity checks to a stored integrity check value associated with the memory block or to a predetermined value.

Example 2: The device according to Example 1, wherein a weak bit corresponds to a stored level of a non-volatile memory cell having a read margin that is less than a minimum acceptable read margin relative to one or more decision levels that define a storage state of the non-volatile memory cell.

Example 3: The device according to any of Examples 1 and 2, wherein the control circuitry is to adjust the read condition of the memory block to the skewed read condition including to: adjust, at least by a determined amount, a reference voltage or current of respective sense amplifiers of the non-volatile memory cells relative to a nominal read reference.

Example 4: The device according to any of Examples 1 through 3, wherein the control circuitry is to adjust the read condition of the memory block to the skewed read condition including to: adjust, at least by a determined amount, a source-to-gate voltage of respective transistors associated with the non-volatile memory cells relative to a nominal read source-to-gate voltage.

Example 5: The device according to any of Examples 1 through 4, wherein the control circuitry is to adjust the read condition of the memory block to the skewed read condition including to: set one or more values of one or more configuration registers used to adjust the read condition of the non-volatile memory cells of the memory block relative to the nominal read condition.

Example 6: The device according to any of Examples 1 through 5, wherein the control circuitry is to adjust the read condition of the memory block to the skewed read condition including to: adjust a signal applied to one or more inputs of the memory to adjust the read condition of the non-volatile memory cells relative to the nominal read condition.

Example 7: The device according to any of Examples 1 through 6, wherein the control circuitry is to determine whether the memory block has at least one weak bit including to: determine the memory block to have the at least one weak bit at least partially based on the results indicating a mismatch between the computed integrity check value and one of the stored integrity check value or the predetermined value; and determine the memory block to be free of weak bits at least partially based on the results indicating a match between the computed integrity check value and one of the stored integrity check value or the predetermined value.

Example 8: The device according to any of Examples 1 through 7, wherein the one or more integrity checks comprise at least one of a cyclic redundancy check (CRC) operation, an error detection and correction (EDAC) operation, or a syndrome-based error detection operation.

Example 9: The device according to any of Examples 1 through 8, wherein the control circuitry is to: perform or initiate performance of the one or more integrity checks on data of the memory block using the skewed read condition.

Example 10: The device according to any of Examples 1 through 9, wherein the control circuitry is to: perform one or more data recovery operations for the non-volatile memory cells of the memory block at least partially responsive to determining the memory block to have the at least one weak bit, the one or more data recovery operations including to: reprogram data in the non-volatile memory cells of the memory block to increase read reliability of the memory block; remap data of the memory block to other available non-volatile memory cells of the memory to increase the read reliability of the memory block; or identify and apply an updated nominal read condition for subsequent reads of the memory block to increase the read reliability of the memory block.

Example 11: The device according to any of Examples 1 through 10, comprising: a processing device including the control circuitry and the memory, the memory comprising embedded memory of the processing device.

Example 12: The device according to any of Examples 1 through 11, comprising: a processing device including the control circuitry and an external memory interface, the external memory interface configured to connect with a memory device that includes the memory.

Example 13: A device comprising: control circuitry to perform operations with respect to memory accessible to the control circuitry, the memory comprising non-volatile memory cells and organized into one or more memory blocks, each memory block comprising one or more data words, the control circuitry to: perform two or more read operations on a memory block of the memory, the two or more read operations including a first read operation and a second read operation; adjust a read condition of the memory block to a skewed read condition for at least one of the two or more read operations on the memory block, the skewed read condition being skewed upward, skewed downward, or both, relative to a nominal read condition; and determine whether the memory block has at least one weak bit at least partially based on comparison between first read data of the first read operation and second read data of the second read operation.

Example 14: The device according to Example 13, wherein a weak bit corresponds to a stored level of a non-volatile memory cell having a read margin that is less than a minimum acceptable read margin relative to one or more decision levels that define a storage state of the non-volatile memory cell.

Example 15: The device according to any of Examples 13 and 14, wherein the control circuitry is to adjust the read condition of the memory block to the skewed read condition including to: adjust, at least by a determined amount, a reference voltage or current of respective sense amplifiers of the non-volatile memory cells relative to a nominal read reference.

Example 16: The device according to any of Examples 13 through 15, wherein the control circuitry is to adjust the read condition of the memory block to the skewed read condition including to: adjust, at least by a determined amount, a source-to-gate voltage of respective transistors associated with the non-volatile memory cells relative to a nominal read source-to-gate voltage.

Example 17: The device according to any of Examples 13 through 16, wherein the control circuitry is to adjust the read condition of the memory block to the skewed read condition including to: set one or more values of one or more configuration registers used to adjust the read condition of the non-volatile memory cells of the memory block relative to the nominal read condition.

Example 18: The device according to any of Examples 13 through 17, wherein the control circuitry is to adjust the read condition of the memory block to the skewed read condition including to: adjust a signal applied to one or more inputs of the memory to adjust the read condition of the non-volatile memory cells relative to the nominal read condition.

Example 19: The device according to any of Examples 13 through 18, wherein the control circuitry is to determine whether the memory block has at least one weak bit including to: determine the memory block to have the at least one weak bit at least partially based on identifying a mismatch between the first read data and the second read data; and determine the memory block to be free of weak bits at least partially based on identifying a match between the first read data and the second read data.

Example 20: The device according to any of Examples 13 through 19, wherein the control circuitry is to: identify at least one weak bit location of the at least one weak bit of the memory block at least partially based on bit differences between corresponding bits of the first read data and the second read data.

Example 21: A non-transitory processor-readable medium that stores processor-executable instructions that, when executed by one or more processors, cause the one or more processors to perform operations with respect to memory accessible to the one or more processors, the memory comprising non-volatile memory cells and organized into one or more memory blocks, each memory block comprising one or more data words, the operations comprising: adjusting a read condition of a memory block of the memory to a skewed read condition for one or more integrity checks on the memory block, the skewed read condition being skewed upward, skewed downward, or both, relative to a nominal read condition; and determining whether the memory block has at least one weak bit at least partially based on results of a comparison of a computed integrity check value from the one or more integrity checks to a stored integrity check value associated with the memory block or to a predetermined value.

Example 22: The non-transitory processor-readable medium that stores the processor-executable instructions according to Example 21, wherein a weak bit corresponds to a stored level of a non-volatile memory cell having a read margin that is less than a minimum acceptable read margin relative to one or more decision levels that define a storage state of the non-volatile memory cell.

Example 23: The non-transitory processor-readable medium that stores the processor-executable instructions according to any of Examples 21 and 22, wherein the operations comprise adjusting the read condition of the memory block to the skewed read condition at least partially by: adjusting, at least by a determined amount, a reference voltage or current of respective sense amplifiers of the non-volatile memory cells relative to a nominal read reference.

Example 24: The non-transitory processor-readable medium that stores the processor-executable instructions according to any of Examples 21 through 23, wherein the operations comprise adjusting the read condition of the memory block to the skewed read condition at least partially by: adjusting, at least by a determined amount, a source-to-gate voltage of respective transistors associated with the non-volatile memory cells relative to a nominal read source-to-gate voltage.

While the disclosure has been described herein with respect to certain illustrated examples, those of ordinary skill in the art will recognize and appreciate that the disclosure is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. A device comprising:
control circuitry to perform operations with respect to memory accessible to the control circuitry, the memory comprising non-volatile memory cells and organized into one or more memory blocks, each memory block comprising one or more data words, the control circuitry to:
adjust a read condition of a memory block of the memory to a skewed read condition for one or more integrity checks on the memory block, the skewed read condition being skewed upward, skewed downward, or both, relative to a nominal read condition; and
determine whether the memory block has at least one weak bit at least partially based on results of a comparison of a computed integrity check value from the one or more integrity checks to a stored integrity check value associated with the memory block or to a predetermined value.

2. The device of claim 1, wherein a weak bit corresponds to a stored level of a non-volatile memory cell having a read margin that is less than a minimum acceptable read margin relative to one or more decision levels that define a storage state of the non-volatile memory cell.

3. The device of claim 1, wherein the control circuitry is to adjust the read condition of the memory block to the skewed read condition including to:
adjust, at least by a determined amount, a reference voltage or current of respective sense amplifiers of the non-volatile memory cells relative to a nominal read reference.

4. The device of claim 1, wherein the control circuitry is to adjust the read condition of the memory block to the skewed read condition including to:
adjust, at least by a determined amount, a source-to-gate voltage of respective transistors associated with the non-volatile memory cells relative to a nominal read source-to-gate voltage.

5. The device of claim 1, wherein the control circuitry is to adjust the read condition of the memory block to the skewed read condition including to:
set one or more values of one or more configuration registers used to adjust the read condition of the non-volatile memory cells of the memory block relative to the nominal read condition.

6. The device of claim 1, wherein the control circuitry is to adjust the read condition of the memory block to the skewed read condition including to:
adjust a signal applied to one or more inputs of the memory to adjust the read condition of the non-volatile memory cells relative to the nominal read condition.

7. The device of claim 1, wherein the control circuitry is to determine whether the memory block has at least one weak bit including to:
determine the memory block to have the at least one weak bit at least partially based on the results indicating a mismatch between the computed integrity check value and one of the stored integrity check value or the predetermined value; and
determine the memory block to be free of weak bits at least partially based on the results indicating a match between the computed integrity check value and one of the stored integrity check value or the predetermined value.

8. The device of claim 1, wherein the one or more integrity checks comprise at least one of a cyclic redundancy check (CRC) operation, an error detection and correction (EDAC) operation, or a syndrome-based error detection operation.

9. The device of claim 1, wherein the control circuitry is to:
perform or initiate performance of the one or more integrity checks on data of the memory block using the skewed read condition.

10. The device of claim 1, wherein the control circuitry is to:
perform one or more data recovery operations for the non-volatile memory cells of the memory block at least partially responsive to determining the memory block to have the at least one weak bit, the one or more data recovery operations including to:
reprogram data in the non-volatile memory cells of the memory block to increase read reliability of the memory block;
remap data of the memory block to other available non-volatile memory cells of the memory to increase the read reliability of the memory block; or
identify and apply an updated nominal read condition for subsequent reads of the memory block to increase the read reliability of the memory block.

11. The device of claim 1, comprising:
a processing device including the control circuitry and the memory, the memory comprising embedded memory of the processing device.

12. The device of claim 1, comprising:
a processing device including the control circuitry and an external memory interface, the external memory interface configured to connect with a memory device that includes the memory.

13. A device comprising:
control circuitry to perform operations with respect to memory accessible to the control circuitry, the memory comprising non-volatile memory cells and organized into one or more memory blocks, each memory block comprising one or more data words, the control circuitry to:
perform two or more read operations on a memory block of the memory, the two or more read operations including a first read operation and a second read operation;
adjust a read condition of the memory block to a skewed read condition for at least one of the two or more read operations on the memory block, the skewed read condition being skewed upward, skewed downward, or both, relative to a nominal read condition; and
determine whether the memory block has at least one weak bit at least partially based on comparison between first read data of the first read operation and second read data of the second read operation.

14. The device of claim 13, wherein a weak bit corresponds to a stored level of a non-volatile memory cell having a read margin that is less than a minimum acceptable read margin relative to one or more decision levels that define a storage state of the non-volatile memory cell.

15. The device of claim 13, wherein the control circuitry is to adjust the read condition of the memory block to the skewed read condition including to:
adjust, at least by a determined amount, a reference voltage or current of respective sense amplifiers of the non-volatile memory cells relative to a nominal read reference.

16. The device of claim 13, wherein the control circuitry is to adjust the read condition of the memory block to the skewed read condition including to:
adjust, at least by a determined amount, a source-to-gate voltage of respective transistors associated with the non-volatile memory cells relative to a nominal read source-to-gate voltage.

17. The device of claim 13, wherein the control circuitry is to adjust the read condition of the memory block to the skewed read condition including to:
set one or more values of one or more configuration registers used to adjust the read condition of the non-volatile memory cells of the memory block relative to the nominal read condition.

18. The device of claim 13, wherein the control circuitry is to adjust the read condition of the memory block to the skewed read condition including to:
adjust a signal applied to one or more inputs of the memory to adjust the read condition of the non-volatile memory cells relative to the nominal read condition.

19. The device of claim 13, wherein the control circuitry is to determine whether the memory block has at least one weak bit including to:
determine the memory block to have the at least one weak bit at least partially based on identifying a mismatch between the first read data and the second read data; and
determine the memory block to be free of weak bits at least partially based on identifying a match between the first read data and the second read data.

20. The device of claim 19, wherein the control circuitry is to:
identify at least one weak bit location of the at least one weak bit of the memory block at least partially based on bit differences between corresponding bits of the first read data and the second read data.

21. A non-transitory processor-readable medium that stores processor-executable instructions that, when executed by one or more processors, cause the one or more processors to perform operations with respect to memory accessible to the one or more processors, the memory comprising non-volatile memory cells and organized into one or more memory blocks, each memory block comprising one or more data words, the operations comprising:
adjusting a read condition of a memory block of the memory to a skewed read condition for one or more integrity checks on the memory block, the skewed read condition being skewed upward, skewed downward, or both, relative to a nominal read condition; and
determining whether the memory block has at least one weak bit at least partially based on results of a comparison of a computed integrity check value from the one or more integrity checks to a stored integrity check value associated with the memory block or to a predetermined value.

22. The non-transitory processor-readable medium that stores the processor-executable instructions of claim 21, wherein a weak bit corresponds to a stored level of a non-volatile memory cell having a read margin that is less than a minimum acceptable read margin relative to one or more decision levels that define a storage state of the non-volatile memory cell.

23. The non-transitory processor-readable medium that stores the processor-executable instructions of claim 21, wherein the operations comprise adjusting the read condition of the memory block to the skewed read condition at least partially by:
adjusting, at least by a determined amount, a reference voltage or current of respective sense amplifiers of the non-volatile memory cells relative to a nominal read reference.

24. The non-transitory processor-readable medium that stores the processor-executable instructions of claim 21, wherein the operations comprise adjusting the read condition of the memory block to the skewed read condition at least partially by:
adjusting, at least by a determined amount, a source-to-gate voltage of respective transistors associated with the non-volatile memory cells relative to a nominal read source-to-gate voltage.
